(19) United States
(12) Patent Application Publication
(10) Pub. No.: US 2025/0204065 A1
(43) Pub. Date: Jun. 19, 2025

(54) IMAGING DEVICE AND ELECTRONIC APPARATUS

(71) Applicant: SONY SEMICONDUCTOR SOLUTIONS CORPORATION, Kanagawa (JP)

(72) Inventors: Akihiro MATSUSHITA, Kanagawa (JP); Yoshihiro MAKITA, Kanagawa (JP); Hikaru OHIRA, Kanagawa (JP)

(73) Assignee: SONY SEMICONDUCTOR SOLUTIONS CORPORATION, Kanagawa (JP)

(21) Appl. No.: 18/846,928

(22) PCT Filed: Mar. 15, 2023
(86) PCT No.: PCT/JP2023/010001

§ 371 Date: Sep. 13, 2024

(30) Foreign Application Priority Data
Mar. 31, 2022 (JP) 2022-058334

(51) Int. Cl. H10F 39/00

(52) U.S. Cl. CPC H10F 39/804; H10F 39/011

(57) ABSTRACT

The present technology relates to an imaging device and an electronic apparatus capable of suppressing generation of a stray light component and improving image quality. A chip on which a photoelectric conversion element is formed, a cover glass, a first bonding portion that bonds the chip and the cover glass together, and a second bonding portion bonded to the first bonding portion and the chip are included, and a bonding surface where the first bonding portion and the second bonding portion are bonded is parallel to the cover glass. The present technology can be applied to, for example, a packaged imaging device.

### TECHNICAL FIELD

The present technology relates to an imaging device and an electronic apparatus, and specifically relates to an imaging device and an electronic apparatus capable of improving image quality.

### BACKGROUND ART

As a structure in which a glass substrate is bonded to a semiconductor substrate in order to encase a pixel region in which a plurality of pixels is arranged, a cavity structure in which a gap is provided between the semiconductor substrate and the glass substrate has been widely adopted (see, for example, Patent Document 1).

### CITATION LIST

### Patent Document

Patent Document 1: Japanese Patent Application Laid-Open No. 2012-175461

### SUMMARY OF THE INVENTION

### Problems to Be Solved by the Invention

The structure in which the semiconductor substrate and the glass substrate are bonded together has a bonding portion where the semiconductor substrate and the glass substrate are bonded together, so that there is a possibility that a stray light component is generated at this bonding portion. It is desired to suppress generation of the stray light component and further improve image quality.

The present technology has been made in view of such circumstances, and it is therefore an object of the present technology to improve image quality.

### Solutions to Problems

An imaging device according to one aspect of the present technology includes: a chip on which a photoelectric conversion element is formed; a cover glass; a first bonding portion that bonds the chip and the cover glass together; and a second bonding portion bonded to the first bonding portion and the chip, in which a bonding surface where the first bonding portion and the second bonding portion are bonded is parallel to the cover glass.

An electronic apparatus according to one aspect of the present technology includes: an imaging device including: a chip on which a photoelectric conversion element is formed; a cover glass; a first bonding portion that bonds the chip and the cover glass together; and a second bonding portion bonded to the first bonding portion and the chip, in which a bonding surface where the first bonding portion and the second bonding portion are bonded is parallel to the cover glass; and a processing unit that processes a signal transmitted from the imaging device.

An imaging device according to one aspect of the present technology includes: a chip on which a photoelectric conversion element is formed; a cover glass; a first bonding portion that bonds the chip and the cover glass together; and a second bonding portion bonded to the first bonding portion and the chip. Furthermore, a bonding surface where the first bonding portion and the second bonding portion are bonded is parallel to the cover glass.

An electronic apparatus according to one aspect of the present technology includes the first imaging device.

Note that the imaging device and the electronic apparatus may be independent devices, or may be internal blocks that constitute one device.

### BRIEF DESCRIPTION OF DRAWINGS

FIG. 1 is a view depicting a configuration of one embodiment of an imaging device to which the present technology is applied.

FIG. 2 is a diagram for describing a portion where a bonding resin is formed.

FIG. 3 is a diagram for describing a stray light component generated.

FIG. 4 is a diagram for describing a size of a bonding portion.

FIG. 5 is a diagram for describing how the imaging device is manufactured.

FIG. 6 is a diagram for describing how the imaging device is manufactured.

FIG. 7 is a diagram for describing how the imaging device is manufactured.

FIG. 8 is a view depicting a configuration of an imaging device according to a second embodiment.

FIG. 9 is a view depicting a configuration of an imaging device according to a third embodiment.

FIG. 10 is a view depicting a configuration of an imaging device according to a fourth embodiment.

FIG. 11 is a view depicting a configuration of an imaging device according to a fifth embodiment.

FIG. 12 is a view depicting a configuration of an imaging device according to a sixth embodiment.

FIG. 13 is a view depicting a configuration of an imaging device according to a seventh embodiment.

FIG. 14 is a diagram for describing how the imaging device is manufactured.

FIG. 15 is a diagram for describing how the imaging device is manufactured.

FIG. 16 is a view depicting a configuration of an imaging device according to an eighth embodiment.

FIG. 17 is a diagram for describing how the imaging device is manufactured.

FIG. 18 is a diagram for describing how the imaging device is manufactured.

FIG. 19 is a view depicting a configuration of an imaging device according to a ninth embodiment.

FIG. 20 is a view depicting a configuration of an imaging device according to a tenth embodiment.

FIG. 21 is a view depicting a configuration of an imaging device according to an eleventh embodiment.

FIG. 22 is a view depicting a configuration of an imaging device according to a twelfth embodiment.

FIG. 23 is a view depicting a configuration of an imaging device according to a thirteenth embodiment.

FIG. 24 is a view depicting a configuration of an imaging device according to a fourteenth embodiment.

FIG. 25 is a view depicting a configuration of an imaging device according to a fifteenth embodiment.

FIG. 26 is a view depicting a configuration of an imaging device according to a sixteenth embodiment.

FIG. 27 is a diagram for describing a configuration example of an electronic apparatus.

FIG. 28 is a view depicting an example of a schematic configuration of an endoscopic surgery system.

FIG. 29 is a block diagram depicting an example of a functional configuration of a camera head and a camera control unit (CCU).

### MODE FOR CARRYING OUT THE INVENTION

Hereinafter, modes for carrying out the present technology (hereinafter referred to as embodiments) will be described.

### Configuration of Imaging Element According to First Embodiment

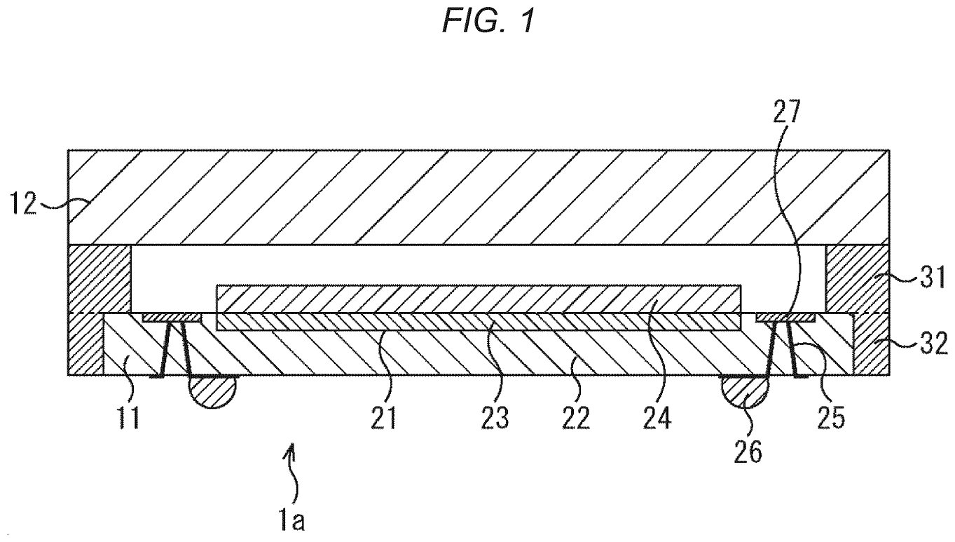

FIG. 1 is a view depicting a configuration of an imaging device 1 (referred to as imaging device 1a) according to a first embodiment. FIG. 1 is a schematic cross-sectional view of the imaging device 1a.

The imaging device 1a includes an imaging element chip 11 and a cover glass 12. The imaging element chip 11 includes, for example, a complementary metal oxide semiconductor (CMOS) image sensor, a charge coupled device (CCD) image sensor, or the like. In an effective pixel region 21 of the imaging element chip 11, a plurality of photoelectric conversion elements (photo diodes: PDs) 23 that converts incident light into charges is provided on a silicon substrate 22

A color filter layer 24 is formed on the photoelectric conversion elements 23 (silicon substrate 22). A microlens (not depicted) may be formed on the color filter layer 24.

A wiring layer is formed under the silicon substrate 22 of the imaging element chip 11 (surface opposite to a light incident surface), and a wiring 25 is formed. The wiring 25 includes aluminum (Al), copper (Cu), or the like, and is formed in an insulating film including an oxide film, a nitride film, or the like.

A predetermined wiring 25 among a plurality of the wirings 25 is connected to an external connection terminal 26 and a surface electrode 27. The external connection terminal 26 is a connection terminal for connection to an external circuit, and is formed under the silicon substrate 22. As the external connection terminal 26, an anisotropic conductive member such as an anisotropic conductive paste (ACP) or an anisotropic conductive film (ACF) using solder balls can also be used.

The imaging element chip 11 and the cover glass 12 are bonded together by a bonding resin 31. A side surface of the silicon substrate 22 is covered with a bonding resin 32.

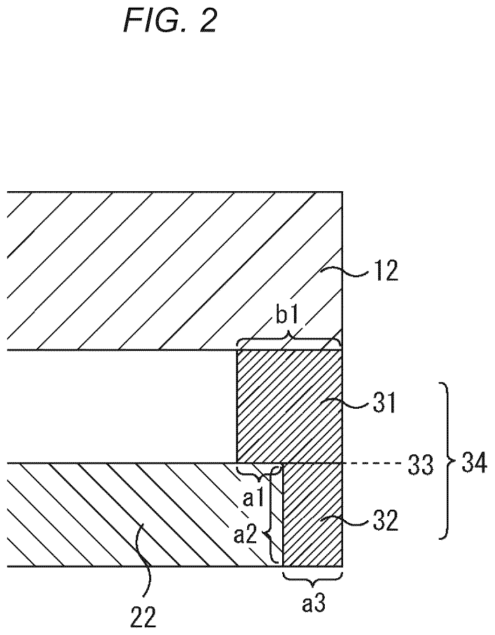

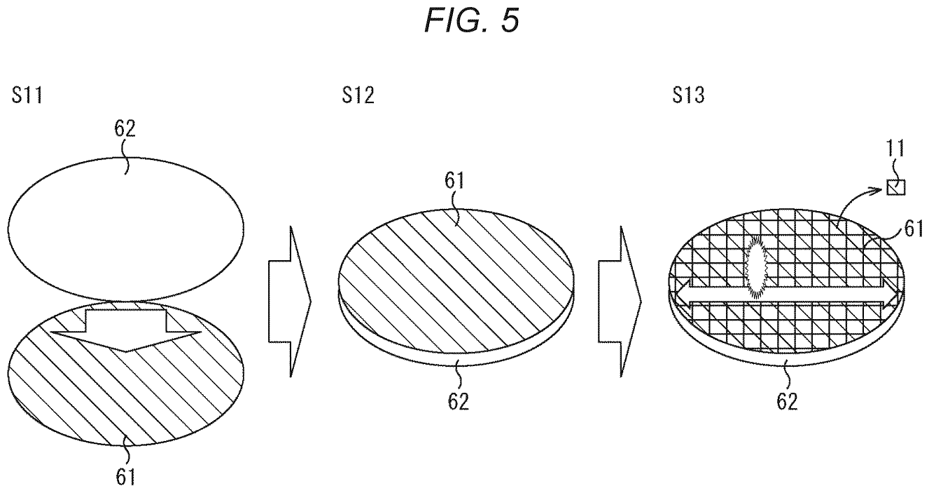

FIG. 2 is an enlarged view of the bonding resin 31 and the bonding resin 32. As will be described later with reference to FIGS. 5 to 7, the bonding resin 31 and the bonding resin 32 are formed at different timings. An interface 33 is located between the bonding resin 31 and the bonding resin 32. Even in the manufactured imaging device 1a, it can be recognized that the interface 33 is present by predetermined analysis, but adhesive strength does not decrease at the interface 33, and the interface 33 is formed with sufficient adhesive strength maintained.

The bonding resin 31 is formed between the imaging element chip 11 and the cover glass 12, and is formed to bond the imaging element chip 11 and the cover glass 12 together. The bonding resin 32 is formed on a side surface of the imaging element chip 11 (side surface of the silicon substrate 22), and is formed to increase bonding strength between the imaging element chip 11 and the cover glass 12 and to protect the silicon substrate 22.

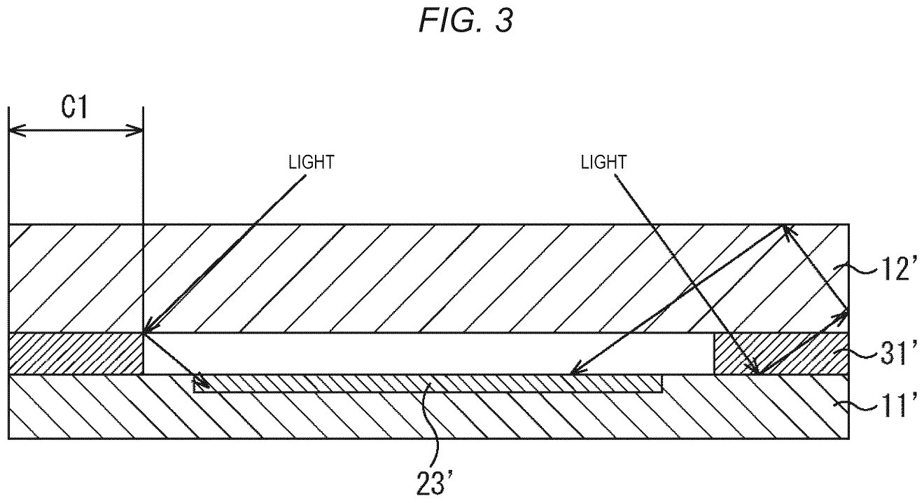

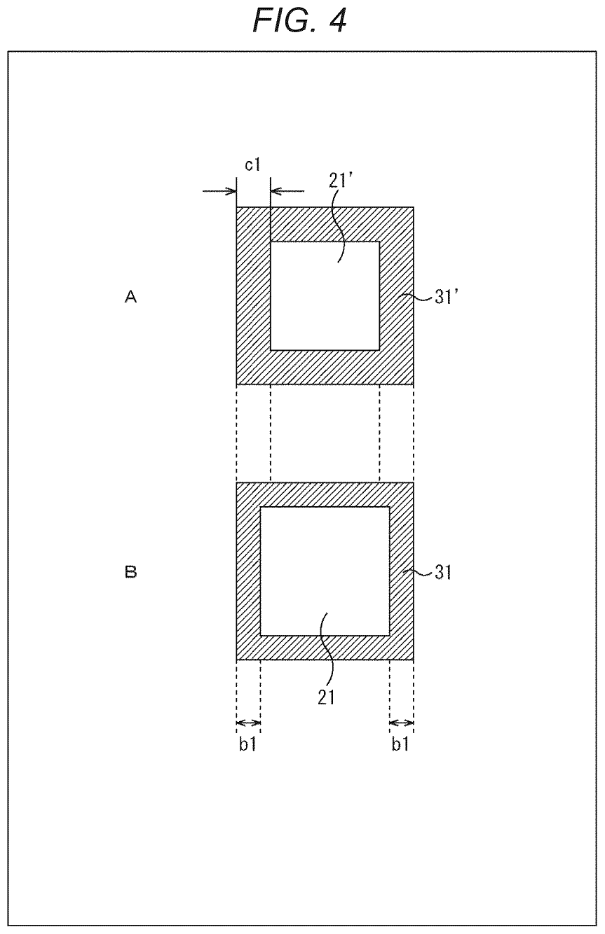

The bonding resin 31 and the bonding resin 31 may include the same material or different materials. The bonding resin 31 formed between the imaging element chip 11 and the cover glass 12 includes, for example, a material with a characteristic of light transmittance of 50% or less in order to suppress stray light incident on a pixel (photoelectric conversion element 23) in the effective pixel region 21. This will be described with reference to FIGS. 3 and 4.

FIG. 3 is a view depicting a configuration of a known imaging device. In an imaging device 1′ (prime is added to indicate that the imaging element is the known imaging element, and the other components are similarly described) depicted in FIG. 3, an imaging element chip 11′ and a cover glass 12′ are bonded together by a bonding resin 31′. The bonding resin 31′ is present only between the imaging element chip 11′ and the cover glass 12′, and is not formed on a side surface of the imaging element chip 11′.

In the imaging device 1′ depicted in FIG. 3, as indicated by an arrow on the left side of the drawing, a part of incident light hits the bonding resin 31′ and is reflected off the bonding resin 31′ to travel toward a photoelectric conversion element 23′. On the right side of FIG. 3, as indicated by an arrow, a part of incident light passes through the bonding resin 31′, and the part of incident light is reflected off a front surface of the silicon substrate 22, reflected off a side surface of the cover glass 12′, and further reflected off an upper surface of the cover glass 12′ to impinge on the photoelectric conversion element 23′.

In order to bond the imaging element chip 11′ and the cover glass 12′ together with sufficient strength, it is necessary to make a width cl of the bonding resin 31′ large enough. This makes it susceptible to the influence of the bonding resin 31′ and also increases a possibility that a stray light component is generated.

In order to prevent such generation of a stray light component due to the bonding resin 31′, the bonding resin 31 of the imaging device 1 depicted in FIG. 1 includes a material having a light-shielding characteristic. The light-shielding characteristic can be a characteristic by which light is prevented from transmitting or light is absorbed, specifically, a characteristic of light transmittance of 50% or less. The bonding resin 31 can include a colored material.

Referring again to FIG. 3, the width of the bonding resin 31′ is set to the width cl. It is assumed that the bonding resin 31′ needs a certain width to achieve sufficient bonding strength between the imaging element chip 11′ and the cover glass 12′, and the width is the width c1.

A of FIG. 4 is a plan view of the imaging device 1′ when the imaging device 1′is viewed from the cover glass 12′ side. As depicted in A of FIG. 4, the bonding resin 31′ is formed around the effective pixel region 21′. The bonding resin 31′ is formed with the width cl.

In a case where the imaging device 1 depicted in FIG. 1 is viewed from the cover glass 12 side as depicted in B of FIG. 4, the bonding resin 31 is formed around the effective pixel region 21 in a similar manner.

The bonding resin 31 is formed with a predetermined width, here, a width b1, on an outer periphery of the imaging element chip 11. The outer periphery of the imaging element chip 11 is a region extending from an end of the effective pixel region 21 to an end of the imaging element chip 11, and the bonding resin 31 is arranged on an outer peripheral portion located adjacent to the end of the imaging element chip 11.

The effective pixel region 21 is encased by the imaging element chip 11, the cover glass 12, and the bonding resin 31. The encased space is referred to as cavity as appropriate. The imaging device 1 as depicted in FIG. 1 is an imaging device having a cavity structure.

As depicted in B of FIG. 4, the width of the bonding resin 31 of the imaging device 1 can be set to the width b1, and the width b1 is smaller than the width c1. As described above, even if the width b1 of the bonding resin 31 is made smaller, the imaging device 1a to which the present technology is applied can maintain a state where the imaging element chip 11 and the cover glass 12 are bonded together with sufficient bonding strength.

Referring again to FIG. 2, the bonding resin 31 is bonded to a lower surface of the cover glass 12 (in the drawing, a surface on the lower side, adjacent to the imaging element chip 11, of the cover glass 12) with the width b1. The bonding resin 31 is bonded to an upper surface of the imaging element chip 11 (in the drawing, a surface on the upper side, adjacent to the cover glass 12, of the imaging element chip 11) with a width a1.

The bonding resin 32 is bonded to the side surface of the imaging element chip 11 with a width a2. Furthermore, the bonding resin 32 is bonded to the bonding resin 31 with a width a3. The relationship the width a1+the width a3=the width b1 holds.

The bonding resin 31 and the bonding resin 32 are bonded together with the width a3 and bonded with sufficient strength. The bonding resin 31 and the bonding resin 32 can be regarded as one bonding resin (hereinafter, referred to as bonding resin 34). The bonding resin 34 is bonded to the imaging element chip 11 with a width obtained by adding up the width a1 and the width a2.

The width obtained by adding up the width a1 and the width a2 is larger than the width c1 (FIG. 3), which allows an increase in area where the bonding resin 34 is in contact with the imaging element chip 11. Therefore, even with the width b1 smaller than the width c1, it is possible to achieve sufficient bonding strength with the imaging element chip 11. As described above, since the bonding resin 31 and the bonding resin 32 have a role of bonding the imaging element chip 11 and the cover glass 12 together, a material having the following characteristics in addition to the light shielding characteristic described above is used as an example.

The bonding resin 31 can include a material with high moisture permeability such as a material primarily including Si (silicon). The bonding resin 31 can include a material with strong adhesion (adhesiveness) to the silicon substrate 22 and the cover glass 12 and can also have a structure including an adhesive layer for increasing adhesion.

The bonding resin 32 can include a material with adhesion to both the bonding resin 32 and the silicon substrate 22 and can also have a structure including an adhesive layer for increasing adhesion. The bonding resin 32 can include a material with low moisture permeability in order to protect the side wall of the silicon substrate 22.

The minimum film thickness of the bonding resin 32 can be greater than or equal to 10 um. According to the present technology, the bonding resin 32 is formed on the side wall of the silicon substrate 22 as described later, so that it is possible to increase the film thickness of the bonding resin 32 to enhance moisture-proof performance or to further enhance protection against impact, heat, and the like. The bonding resin 32 may include the same material as of the bonding resin 31.

In a case where the bonding resin 31 and the bonding resin 32 include the same material, it is possible to increase adhesion of both the materials and to reduce cost. In a case where the bonding resin 31 and the bonding resin 32 include different materials, the bonding resins can each include a material suitable for their respective purposes, and a material with improved product performance and reliability can be selectively used.

### Method for Manufacturing Imaging Device 1a According to First Embodiment

A method for manufacturing the imaging device 1a in FIG. 1 will be described with reference to FIGS. 5 to 7.

How to manufacture the imaging element chip 11 will be described with reference to FIG. 5. In step S11, a semiconductor wafer 61 in which a plurality of pixel regions each including the photoelectric conversion element 23 is formed on a substrate including monocrystalline silicon is prepared. A protective sheet 62 for protecting the photoelectric conversion element 23 and the like formed on the semiconductor wafer 61 is adhered to a surface of the semiconductor wafer 61 on which the photoelectric conversion element 23 and the like are formed.

In step S11, the protective sheet 62 and a support substrate (not depicted) may be both adhered to the semiconductor wafer 61. Further adhering the support substrate makes processing such as thinning of the semiconductor wafer 61, wiring formation, and the like performed in steps subsequent to step S12 easier.

In step S12, the semiconductor wafer 61 to which the protective sheet 62 is adhered is turned over, and a side of the semiconductor wafer 61 on which no photoelectric conversion element 23 is formed is processed to make the semiconductor wafer 61 thinner. After the thinning, the wiring 25 (redistribution layer (RDL)) for connection to the external connection terminal 26, a through electrode for connecting the wiring 25 to the surface electrode 27, and the like are formed in the semiconductor wafer 61. When the wiring is formed in step S12, the external connection terminal 26 (solder ball) may also be formed.

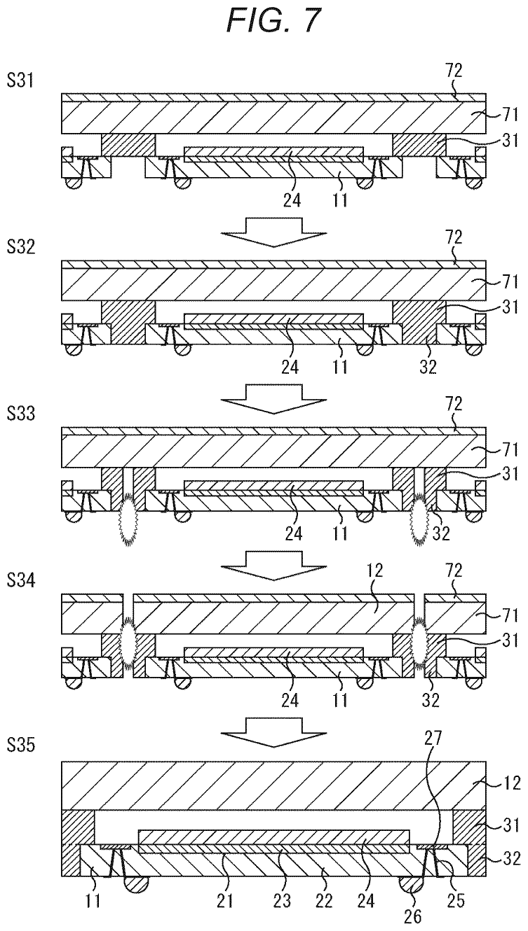

In step S13, dicing is performed to dice the semiconductor wafer 61 into separate imaging element chips 11. Step S13 is a state where the protective sheet 62 is not diced, and the separate imaging element chips 11 remain adhered to the protective sheet 62. In step S31 (FIG. 7) to be described later, the imaging element chips 11 are removed from the protective sheet 62 and are arranged on the cover glass 12 in a wafer state.

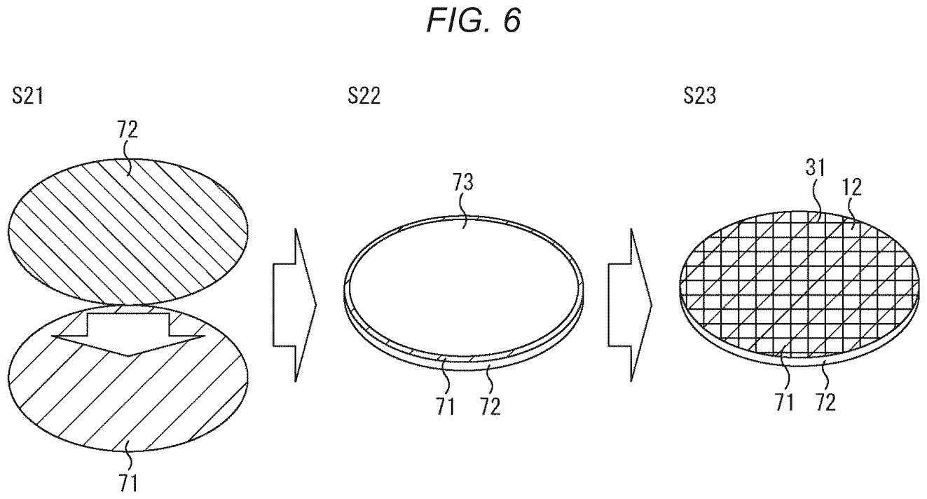

A step relating to the cover glass 12 will be described with reference to FIG. 6. In step S21, a glass substrate 71 that is a substrate to be the cover glass 12 and is manufactured with about the same size as of the semiconductor wafer 61 is prepared. The protective sheet 72 for preventing scratches caused on the glass substrate 71 during processing such as dicing in the subsequent steps is adhered to the glass substrate 71.

In step S22, the glass substrate 71 to which the protective sheet 72 is adhered is turned over, and a non-light transmitting resin 73 to be the bonding resin 31 is applied to all over the glass substrate 71. The non-light transmitting resin 73 may be a sheet resin.

In step S23, the non-light transmitting resin 73 is processed to form a portion to be the bonding resin 31. A region from which the non-light transmitting resin 73 is removed, in other words, a region to be an opening is an opening region smaller than the imaging element chip 11. The portion to be the bonding resin 31 may be formed by patterning the non-light transmitting resin 73, or by direct pattern formation using a stencil mask or the like.

In step S23, the opening size of the non-light transmitting resin 73 can be set as desired. A line width of the non-light transmitting resin 73 left as a result of forming the opening is equal to a line width obtained by adding a dicing width to a line width that corresponds to two lines of the bonding resin 31, specifically, in a case where the bonding resin 31 is formed with the width b1 as depicted in FIG. 2, a line width twice the width b1. As depicted in FIG. 2, the width b1 includes the width a3 with which the bonding resin 31 and the bonding resin 32 are in contact with each other, and the line width of the non-light transmitting resin 73 to be left is determined with the degree of the width a3 also taken into account.

A step relating to packaging of the imaging device 1a will be described with reference to FIG. 7. In step S31, the imaging element chips 11 separated in step S13 are removed from the protective sheet 62, and are each placed on and bonded to the glass substrate 71 on which the bonding resin 31 is formed in step S23.

As depicted in step S31 in FIG. 7, the imaging element chip 11 is placed with both ends placed on the bonding resin 31. FIG. 7 shows a state when viewed in cross section, but, in plan view, the bonding resin 31 is located on the outer peripheral portion of the imaging element chip 11, and the imaging element chip 11 is arranged on the bonding resin 31 having a region corresponding to the effective pixel region 21 opened.

As depicted in step S31 in FIG. 7, the imaging element chips 11 are arranged at predetermined intervals. The center of this interval is a portion to be a scrub line.

In step S31, the imaging element chips 11 are arranged on the glass substrate 71 to be the cover glass 12, so that even imaging element chips 11 having different sizes can be arranged on the glass substrate 71. In a case where the imaging element chips 11 having different sizes are arranged, when patterning the non-light transmitting resin 73 in step S23 (FIG. 6), patterning having an opening corresponding to each imaging element chip 11 to be arranged is performed. This allows the imaging element chips 11 to be efficiently arranged on the semiconductor wafer 61, and the yield can be increased.

In step S32, a gap between the imaging element chips 11 is filled with a material to be the bonding resin 32. The process in step S32 is performed after the bonding resin 31 hardens.

In steps S33 and S34, dicing is performed to form separate imaging devices 1a. FIG. 7 depicts the step of dicing the bonding resin 31 and the bonding resin 32 in step S33 and the step of dicing the glass substrate 71 in step S34. As described above, a blade may be changed when the bonding resin is diced and when the glass substrate 71 is diced, or dicing may be performed at a time, that is, the bonding resin and the glass substrate 71 may be diced without dividing the dicing step into step S33 and step S34.

In step S35, the protective sheet 72 is removed from each separate imaging device 1a, and as a result, the manufacturing of the imaging device 1a is complete.

As described above, the imaging device 1a is manufactured. Since the bonding resin 31 and the bonding resin 32 are formed in steps S23 and S32, respectively, the interface 33 exists between the bonding resin 31 and the bonding resin 32 as described with reference to FIG. 2.

Since the bonding resin 31 and the bonding resin 32 are formed in separate steps, the bonding resin 31 and the bonding resin 32 can be easily formed with different materials, and materials with desired characteristics can be selectively used. In a case where the imaging device 1 is manufactured through such steps, the interface 33 serves as a bonding surface between the bonding resin 31 and the bonding resin 32, and this bonding surface is flush with or slightly displaced relative to the upper surface of the imaging element chip 11 (front surface of the imaging element chip 11).

The interface 33 is parallel to the front surface of the imaging element chip 11, a back surface of the cover glass 12, and the like. If the interface 33 is not parallel to the cover glass 12, when the imaging element chip 11 is arranged on the bonding resin 31, there is a possibility that the imaging element chip 11 is arranged at an angle relative to the cover glass 12. Therefore, the surface of the bonding resin 31 on which the imaging element chip 11 is arranged is formed in parallel with the cover glass 12. Since the bonding resin 32 fills the gap on the bonding resin 31, the bonding surface (interface 33) between the bonding resin 31 and the bonding resin 32 is parallel to the cover glass 12.

As described above, since the packaging is performed after the wiring layer of the silicon substrate 22 is formed, it is possible to reduce the influence of warpage during the manufacturing process.

### Configuration of Imaging Device According to Second Embodiment

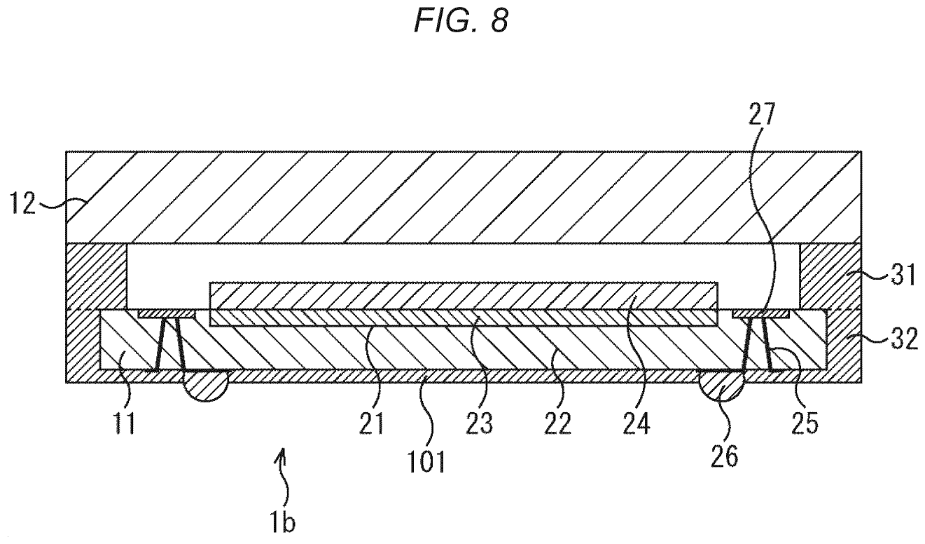

FIG. 8 is a diagram depicting a configuration example of an imaging device 1b according to a second embodiment. In the following description, the same components as of the imaging device 1a according to the first embodiment depicted in FIG. 1 are denoted by the same reference numerals, and detailed description thereof will be omitted as appropriate.

The imaging device 1b depicted in FIG. 8 is the same as the imaging device 1a depicted in FIG. 1 except that a protective film 101 is formed on a surface (referred to as back surface) of the imaging element chip 11 on which the external connection terminal 26 is formed.

The protective film 101 is provided as a film for protecting a wiring layer formed on the back surface of the imaging element chip 11 (silicon substrate 22), and is formed all over the back surface other than the external connection terminal 26. It is possible to protect, by providing the protective film 101, the side surface and the back surface of the imaging element chip 11.

The protective film 101 can include the same material as of the bonding resin 32. In a case where the protective film 101 includes the same material as of the bonding resin 32, the protective film 101 can be formed at the same time as when the gap between the imaging element chips 11 is filled with the bonding resin 32 in step S32 (FIG. 7) during manufacturing.

### Configuration of Imaging Device According to Third Embodiment

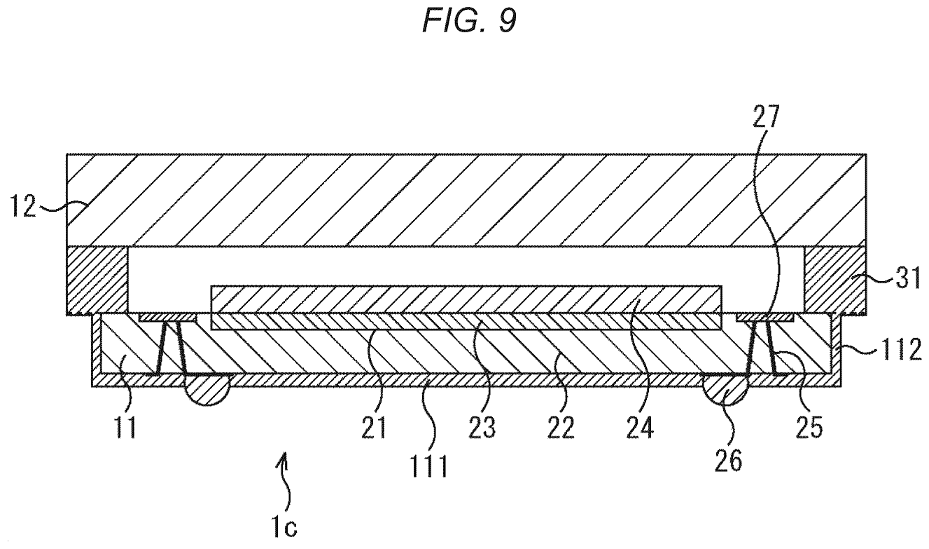

FIG. 9 is a diagram depicting a configuration example of an imaging device 1c according to a third embodiment.

The imaging device 1c depicted in FIG. 9 is the same as the imaging device 1a depicted in FIG. 1 except that a protective film 111 is formed on the surface of the imaging element chip 11 on which the external connection terminal 26 is formed, and a bonding resin 112 formed on the side surface is formed thinner.

As with the protective film 101 of the imaging device 1b depicted in FIG. 8, the protective film 111 is provided as a film for protecting the wiring layer formed on the back surface of the imaging element chip 11 (silicon substrate 22), and is formed all over the back surface other than the external connection terminal 26. The imaging element chip 11 of the imaging device 1c has the side surface covered with the bonding resin 112.

The protective film 111 and the bonding resin 112 can include the same material. In a case where the protective film 111 and the bonding resin 112 include the same material, it is only required to form, in step S32 (FIG. 7), the bonding resin 112 with a film thickness that allows the bonding resin 112 and the bonding resin 31 to be bonded together with sufficient strength and allows protection of the imaging element chip 11, rather than forming the bonding resin 112 by causing the bonding resin 112 completely filling the gap between the imaging element chips 11. Furthermore, at this time, the protective film 111 can also be formed.

The bonding resin 112 can be formed with a film thickness of, for example, 10 um or more, and the protective film 111 can also be formed with a film thickness of, for example, 10 um or more.

### Configuration of Imaging Device According to Fourth Embodiment

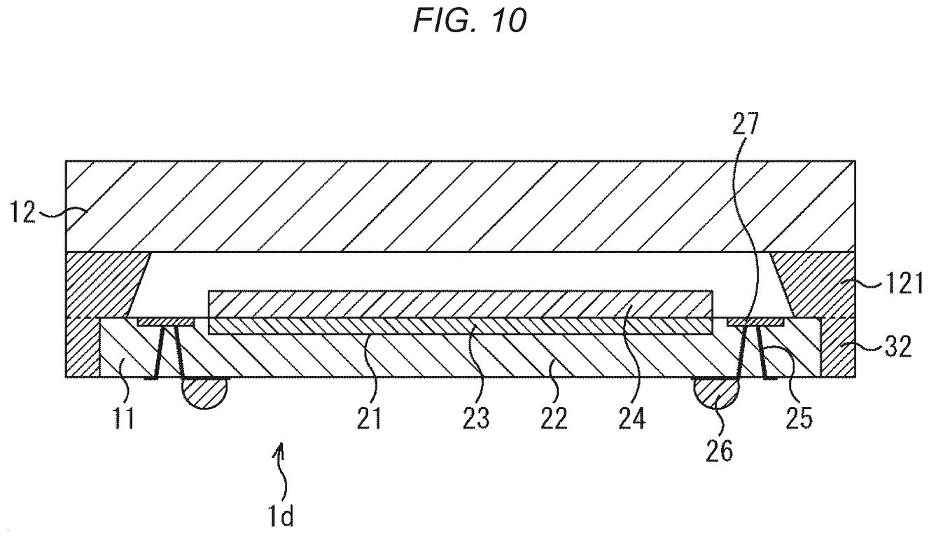

FIG. 10 is a diagram depicting a configuration example of an imaging device 1d according to a fourth embodiment.

The imaging device 1d depicted in FIG. 10 is the same as the imaging device 1a depicted in FIG. 1 except that a bonding resin 121 provided between the imaging element chip 11 and the cover glass 12 is formed in a tapered shape.

In the imaging device 1d, a side, adjacent to the cavity, of the bonding resin 121 is formed in a tapered shape. In other words, the bonding resin 121 is formed at an angle between the imaging element chip 11 and the cover glass 12.

In the example depicted in FIG. 10, the bonding resin 121 is formed in a shape that becomes wider from the imaging element chip 11 side toward the cover glass 12 side. Forming the bonding resin 121 in a tapered shape makes it possible to suppress stray light caused by the ends of the bonding resin 121. Furthermore, an area where the bonding resin 121 and the cover glass 12 are in contact with each other can be increased, and bonding strength between the bonding resin 121 and the cover glass 12 can be increased accordingly.

The imaging device 1d may have a configuration where, as with the imaging device 1b (FIG. 8) and the imaging device 1c (FIG. 9), a protective film corresponding to the protective film 101 (111) is formed on the back surface of the imaging element chip 11.

### Configuration of Imaging Device According to Fifth Embodiment

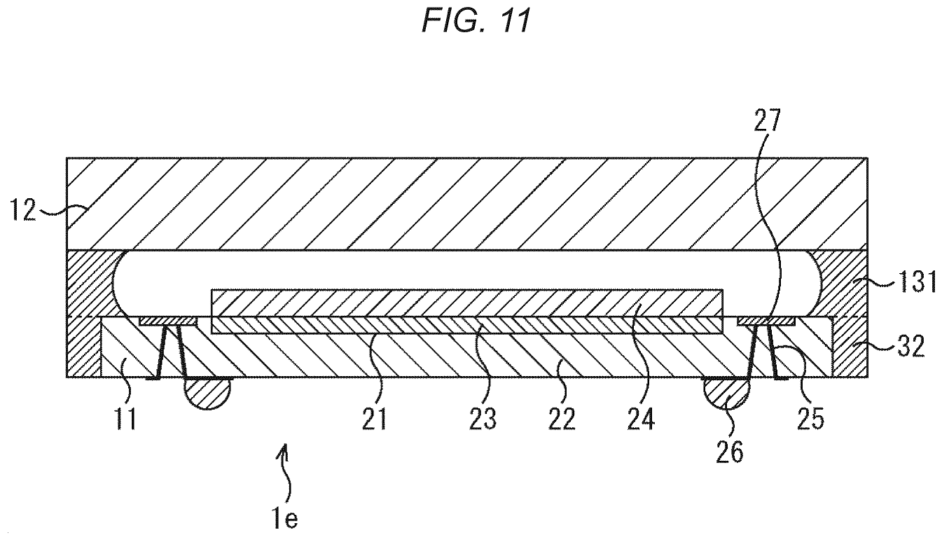

FIG. 11 is a diagram depicting a configuration example of an imaging device le according to a fifth embodiment.

The imaging device le depicted in FIG. 11 is the same as the imaging device 1a depicted in FIG. 1 except that a bonding resin 131 provided between the imaging element chip 11 and the cover glass 12 is formed in a semicircular arc shape.

In the imaging device 1e, a side, adjacent to the cavity, of the bonding resin 131 is formed in a semicircular arc shape, in other words, at an angle. Forming the bonding resin 131 in a semicircular arc shape makes it possible to suppress stray light caused by the ends of the bonding resin 131.

Furthermore, an area where the bonding resin 131 and the cover glass 12 are in contact with each other can be increased, thereby allowing an increase in bonding strength between the bonding resin 131 and the cover glass 12. An area where the bonding resin 131 and the imaging element chip 11 are in contact with each other can be increased, and bonding strength between the bonding resin 131 and the imaging element chip 11 can also be increased accordingly.

The imaging device le may have a configuration where, as with the imaging device 1b (FIG. 8) and the imaging device 1c (FIG. 9), a protective film corresponding to the protective film 101 (111) is formed on the back surface of the imaging element chip 11.

According to the present technology, since the width of the bonding resin (for example, the bonding resin 31 depicted in FIG. 1) that bonds the imaging element chip 11 and the cover glass 12 together can be reduced, and sufficient bonding strength can be achieved even if the width is reduced, the imaging device 1 can be reduced in size.

Protecting the side surface of the imaging element chip 11 with the bonding resin (for example, the bonding resin 32 depicted in FIG. 1) allows an increase in product reliability.

### Configuration of Imaging Device According to Sixth Embodiment

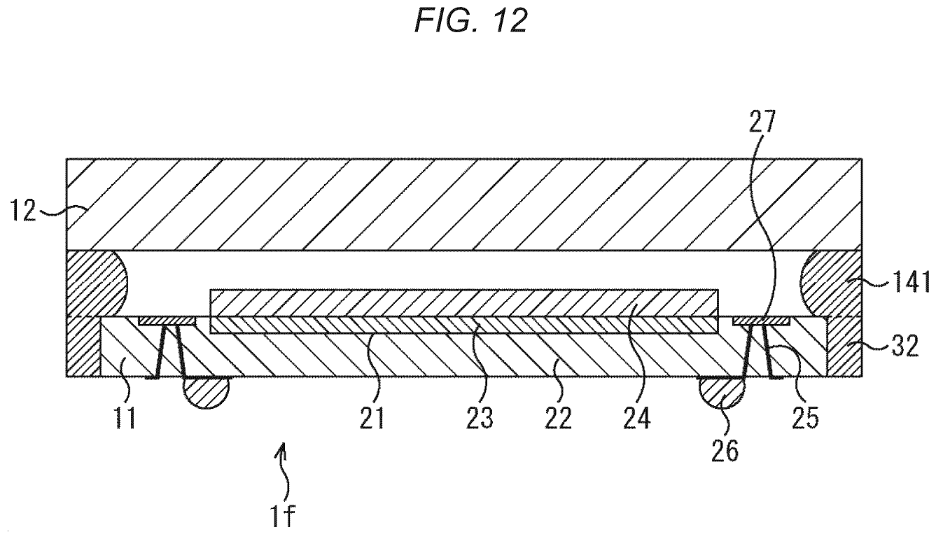

FIG. 12 is a diagram depicting a configuration example of an imaging device If according to a sixth embodiment.

The imaging device If depicted in FIG. 12 is the same as the imaging device le depicted in FIG. 11 except that a bonding resin 141 provided between the imaging element chip 11 and the cover glass 12 is formed in a semicircular arc shape (curved shape), and the semicircular arc shape curves toward the cavity in the middle.

In the imaging device If, a side, adjacent to the cavity, of the bonding resin 141 is formed in a semicircular arc shape, in other words, at an angle. The bonding resin 141 of the imaging device If is formed in a semicircular arc shape that curves toward the cavity in the middle. Forming the bonding resin 141 in a semicircular arc shape makes it possible to suppress stray light caused by the ends of the bonding resin 141.

Furthermore, an area where the bonding resin 141 and the cover glass 12 are in contact with each other can be increased, and bonding strength between the bonding resin 141 and the cover glass 12 can be increased accordingly. An area where the bonding resin 141 and the imaging element chip 11 (bonding resin 32) are in contact with each other can be increased, and bonding strength between the bonding resin 141 and the imaging element chip 11 can also be increased accordingly.

The imaging device If may have a configuration where, as with the imaging device 1b (FIG. 8) and the imaging device 1c (FIG. 9), a protective film corresponding to the protective film 101 (111) is formed on the back surface of the imaging element chip 11.

### Configuration of Imaging Device According to Seventh Embodiment

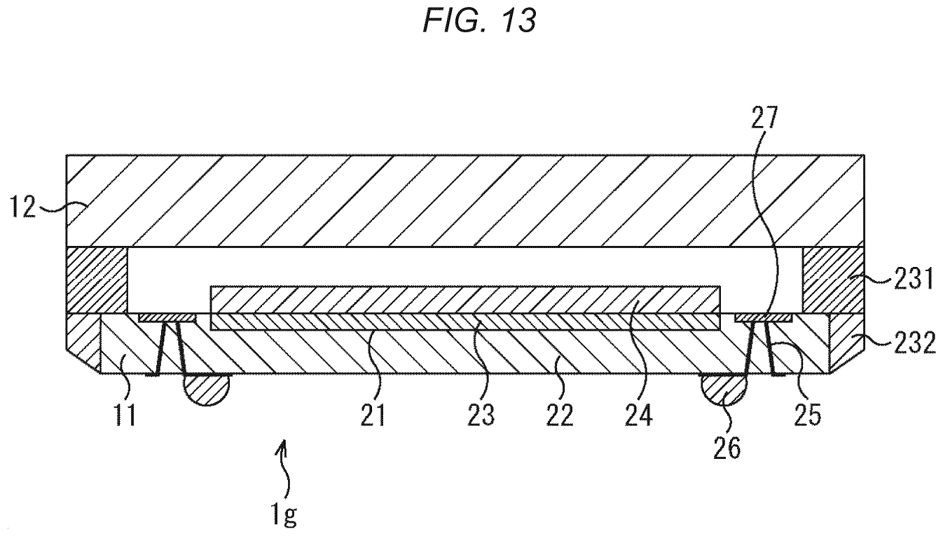

FIG. 13 is a diagram depicting a configuration example of an imaging device 1g according to a seventh embodiment.

The imaging device 1g depicted in FIG. 13 is the same as the imaging device 1a depicted in FIG. 1 except that a bonding resin 232 provided on the side surface of the imaging element chip 11 is formed in a trapezoidal shape. The bonding resin 232 of the imaging device 1g depicted in FIG. 13 has a trapezoidal shape, and has one of the four sides bonded to the side surface of the imaging element chip 11 and another side bonded to the bonding resin 231.

Of the four sides of the trapezoidal bonding resin 232, one of the two sides bonded to neither the imaging element chip 11 nor the bonding resin 231 may have a linear shape or a bent (curved) shape. In the example depicted in FIG. 13, the lower side of the bonding resin 232 in the drawing is formed in a linear shape, but the present embodiment also includes a case where the side is bent, depending on the manufacturing process or the like.

Also in the imaging device 1g, for example, forming the bonding resin 231 with the same material and in the same shape as of the bonding resin 31 of the imaging device 1a in FIG. 1 makes it possible to suppress stray light caused by the ends of the bonding resin 131. The bonding resin 231 may include a resin with high thermal conductivity (coefficient of thermal conductivity) (hereinafter, referred to as high thermal conductivity resin). The imaging device 1g has a tendency that the amount of heat generation increases with higher performance and higher throughput, and it is desirable to have a structure capable of efficiently dissipating heat.

The use of the high thermal conductivity resin as the bonding resin 231 achieves a structure that dissipates heat generated by the imaging element chip 11 from the bonding resin 231 to the outside. The bonding resin 31 and the like according to the above-described embodiments can also be the high thermal conductivity resin. The bonding resin 231 may be a high thermal conductivity resin with light transmittance of 50% or less.

For example, forming the bonding resin 231 in the same shape as of the bonding resin 31 of the imaging device 1a in FIG. 1 allows an increase in area where the bonding resin 231 and the cover glass 12 are in contact with each other and allows an increase in bonding strength between the bonding resin 231 and the cover glass 12. An area where the bonding resin 231 and the imaging element chip 11 (bonding resin 32) are in contact with each other can be increased, and bonding strength between the bonding resin 231 and the imaging element chip 11 can also be increased accordingly.

The imaging device 1g may have a configuration where, as with the imaging device 1b (FIG. 8) and the imaging device 1c (FIG. 9), a protective film corresponding to the protective film 101 (111) is formed on the back surface of the imaging element chip 11.

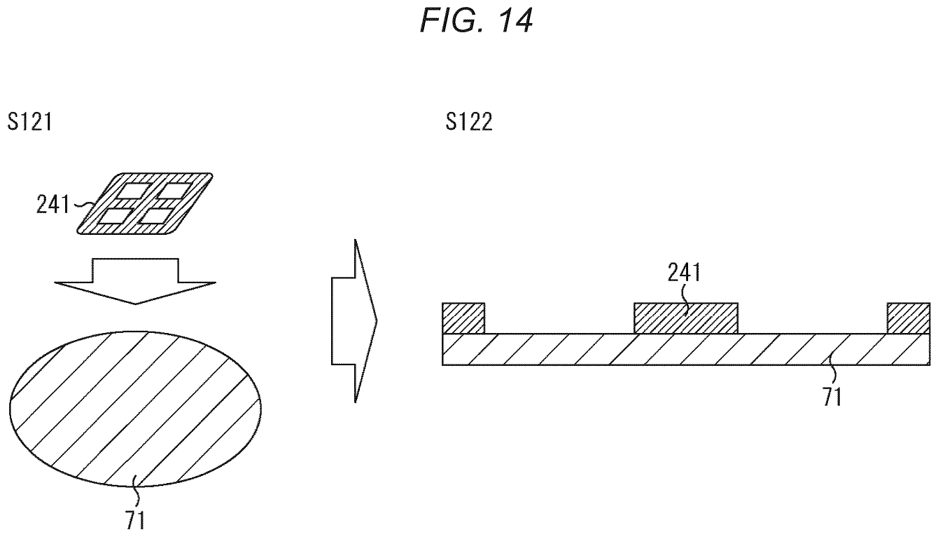

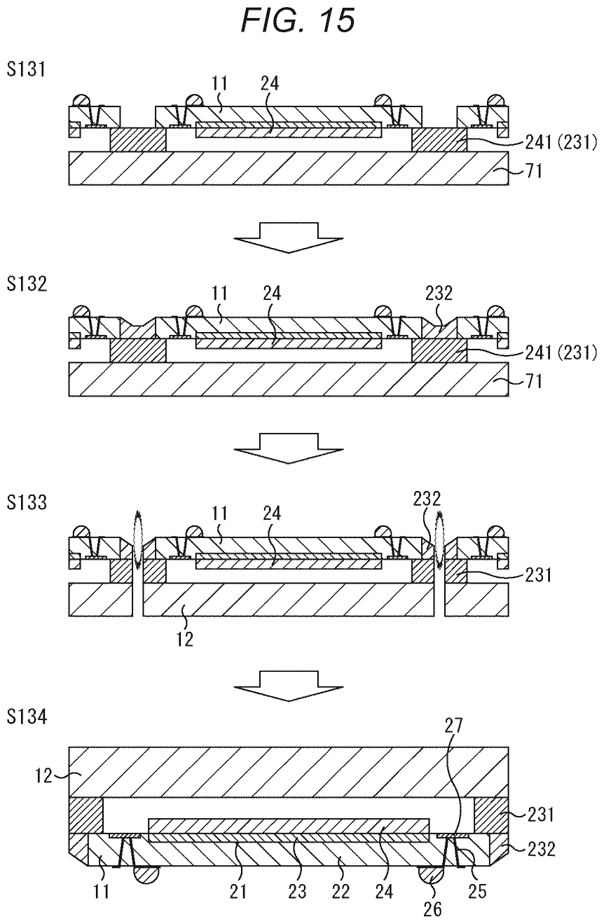

How to manufacture the imaging device 1g depicted in FIG. 13 will be described with reference to FIGS. 14 and 15. Here, a case where the high thermal conductivity resin is used as the bonding resin 231 will be described as an example.

How to manufacture the imaging element chip 11 is similar to the case described with reference to FIG. 5, so that the description of how to manufacture the imaging element chip 11 will be omitted here.

A step relating to the cover glass 12 will be described with reference to FIG. 14. In step S121, the glass substrate 71 that is a substrate to be the cover glass 12 and is manufactured with about the same size as of the semiconductor wafer 61 is prepared. In step S121, a high thermal conductivity resin frame 241 to be the bonding resin 231 is also prepared all over the glass substrate 71. A shape of the high thermal conductivity resin frame 241 can be freely designed using a desired mold.

The high thermal conductivity resin frame 241 is a frame provided with a rectangular opening, and is a portion to be the bonding resin 231 including the high thermal conductivity resin after the end of processing such as dicing in the subsequent steps. This step may include a step of adhering, to the glass substrate 71, a protective sheet for preventing scratches caused on the glass substrate 71 during processing such as dicing in the subsequent steps.

In step S122, the high thermal conductivity resin frame 241 is adhered to the glass substrate 71. The opening of the high thermal conductivity resin frame 241 is an opening region smaller than the imaging element chip 11.

A step relating to packaging of the imaging device 1g will be described with reference to FIG. 15. In step S131, the imaging element chips 11 separated in step S12 (FIG. 5) are removed from the protective sheet 62 and are each placed on and bonded to the glass substrate 71 to which the high thermal conductivity resin frame 241 is adhered in step S122.

As depicted in step S131 in FIG. 15, the imaging element chip 11 is placed with both ends placed on the high thermal conductivity resin frame 241 (region to be the bonding resin 231). FIG. 15 shows a state when viewed in cross section, but, in plan view, the high thermal conductivity resin frame 241 (bonding resin 231) is located on the outer peripheral portion of the imaging element chip 11, and the imaging element chip 11 is arranged on the bonding resin 231 having a region corresponding to the effective pixel region 21 opened.

As depicted in step S131 in FIG. 15, the imaging element chips 11 are arranged at predetermined intervals. The center of this interval is a portion to be a scrub line.

In step S132, a gap between the imaging element chips 11 is filled with a material to be the bonding resin 232.

In step S133, dicing is performed to form separate imaging devices 1g. The bonding resin 231 and the bonding resin 232 are diced, and the glass substrate 71 is diced, so as to form separate imaging devices 1g.

In step S134, the manufacturing of the separate imaging device 1g is complete.

### Configuration of Imaging Device According to Eighth Embodiment

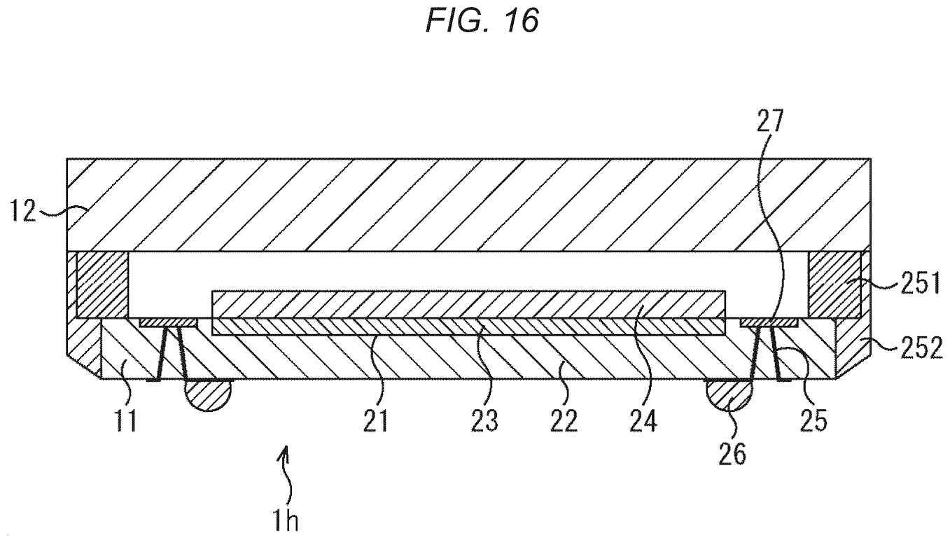

FIG. 16 is a diagram depicting a configuration example of an imaging device 1h according to an eighth embodiment.

The imaging device 1h depicted in FIG. 16 is the same as the imaging device 1a depicted in FIG. 1 except that a bonding resin 252 provided on the side surface of the imaging element chip 11 is formed in a trapezoidal shape and is further formed on a side wall of a bonding resin 251. The bonding resin 252 of the imaging device 1h depicted in FIG. 16 has a trapezoidal shape, and has one of the four sides bonded to the side surface of the imaging element chip 11 and another side partially bonded to a bottom side of the bonding resin 252.

The bonding resin 252 is further formed on the side surface of the bonding resin 251. In other words, the side surface of the bonding resin 251 is covered with a material constituting the bonding resin 252.

Also in the imaging device 1h, for example, forming the bonding resin 251 with the same material and in the same shape as of the bonding resin 31 of the imaging device 1a in FIG. 1 makes it possible to suppress stray light caused by the ends of the bonding resin 131. The bonding resin 251 can also be formed with a high thermal conductivity resin. The bonding resin 251 may also be formed with metal as a material.

For example, forming the bonding resin 252 with the same material and in the same shape as of the bonding resin 31 of the imaging device 1a in FIG. 1 allows an increase in area where the bonding resin 252 and the cover glass 12 are in contact with each other and allows an increase in bonding strength between the bonding resin 252 and the cover glass 12. An area where the bonding resin 252 and the imaging element chip 11 are in contact with each other can be increased, and bonding strength between the bonding resin 252 and the imaging element chip 11 can also be increased accordingly.

The imaging device 1h may have a configuration where, as with the imaging device 1b (FIG. 8) and the imaging device 1c (FIG. 9), a protective film corresponding to the protective film 101 (111) is formed on the back surface of the imaging element chip 11.

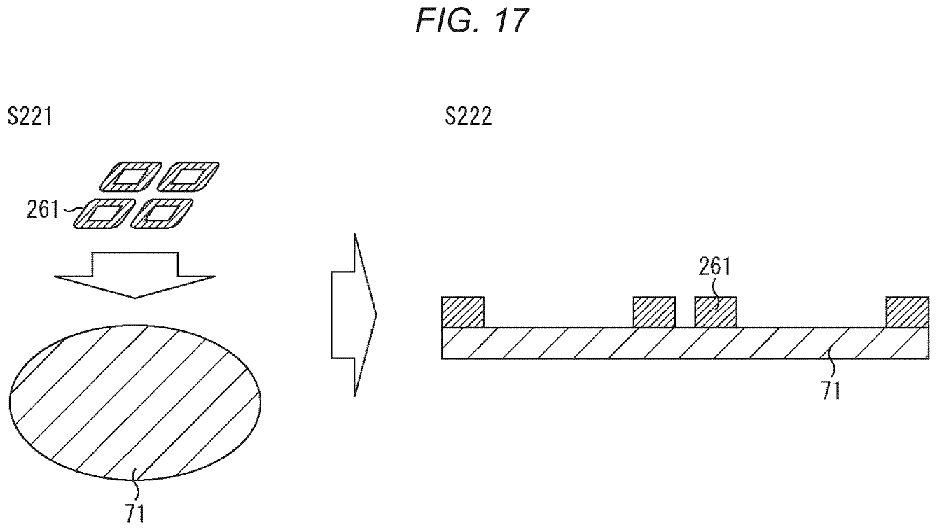

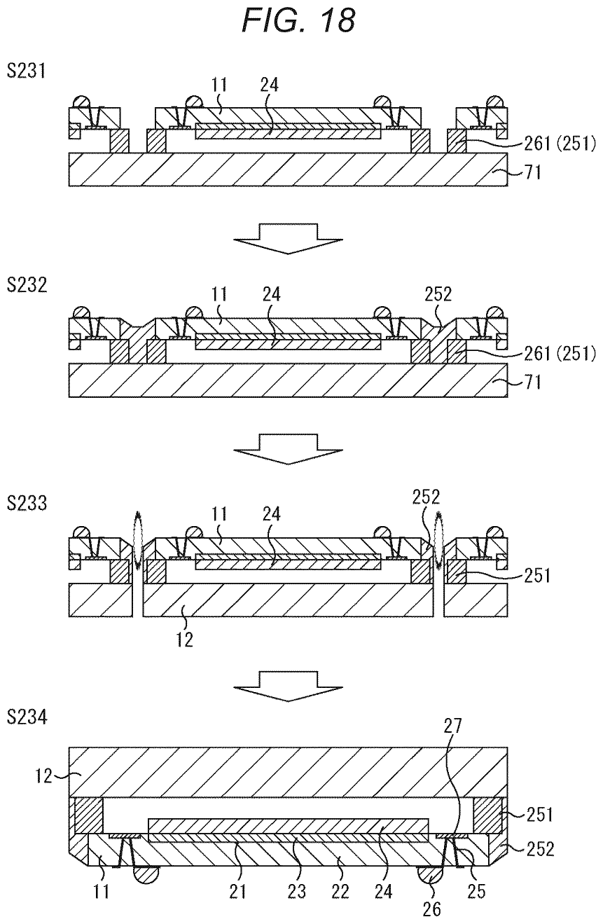

How to manufacture the imaging device 1h depicted in FIG. 16 will be described with reference to FIGS. 17 and 18. Here, a case where metal is used for the bonding resin 252 will be described as an example.

How to manufacture the imaging element chip 11 is similar to the case described with reference to FIG. 5, so that the description of how to manufacture the imaging element chip 11 will be omitted here.

A step relating to the cover glass 12 will be described with reference to FIG. 17. In step S221, the glass substrate 71 that is a substrate to be the cover glass 12 and is manufactured with about the same size as of the semiconductor wafer 61 is prepared. In step S221, a metal frame 261 to be the bonding resin 252 is also prepared all over the glass substrate 71. A shape of the metal frame 261 can be freely designed using a desired mold.

The metal frame 261 is a frame provided with a rectangular opening, and is a portion to be the bonding resin 251 including metal after processing such as dicing in the subsequent steps. This step may include a step of adhering, to the glass substrate 71, a protective sheet for preventing scratches caused on the glass substrate 71 during processing such as dicing in the subsequent steps.

In step S222, the metal frame 261 is adhered to the glass substrate 71. The opening of the metal frame 261 is an opening region smaller than the imaging element chip 11. The metal frame 261 is a frame having square-shaped bonding resins 251 with openings arranged at predetermined intervals. The predetermined interval may be about the same as or larger than a width of a scrubbing line.

A step relating to packaging of the imaging device 1h will be described with reference to FIG. 18. In step S231, the imaging element chips 11 separated in step S22 (FIG. 5) are removed from the protective sheet 62 and are each placed on and bonded to the glass substrate 71 to which the metal frame 261 is adhered in step S222 (FIG. 17).

As depicted in step S231 in FIG. 18, the imaging element chip 11 is placed with both ends placed on the metal frame 261 (region to be the bonding resin 251). FIG. 18 shows a state when viewed in cross section, but, in plan view, the metal frame 261 (bonding resin 251) is located on the outer peripheral portion of the imaging element chip 11, and the imaging element chip 11 is arranged on the bonding resin 251 having a region corresponding to the effective pixel region 21 opened.

As depicted in step S231 in FIG. 18, the imaging element chips 11 are arranged at predetermined intervals. The center of this interval is a portion to be a scrub line. The portion to be the scrub line is a gap in the metal frame 261, so that there is no metal frame 261 in the portion to be the scrub line.

In step S232, a gap between the imaging element chips 11 is filled with a material to be the bonding resin 251. A gap between the metal frames 261, in other words, a gap between the bonding resins 251, is filled, in a similar manner, with a material to be the bonding resin 252.

In step S233, dicing is performed to form separate imaging devices 1h. The bonding resin 252 and the bonding resin 251 are diced, and the glass substrate 71 is diced, so as to form separate imaging devices 1h. At the time of the dicing, since the gap between the metal frames 261 is also filled with the bonding resin 252, the metal frames 261 are separated with the bonding resin 252 remaining on the side surface of each metal frame 261.

In step S234, the manufacturing of the separate imaging device 1h is complete.

### Configuration of Imaging Device According to Ninth Embodiment

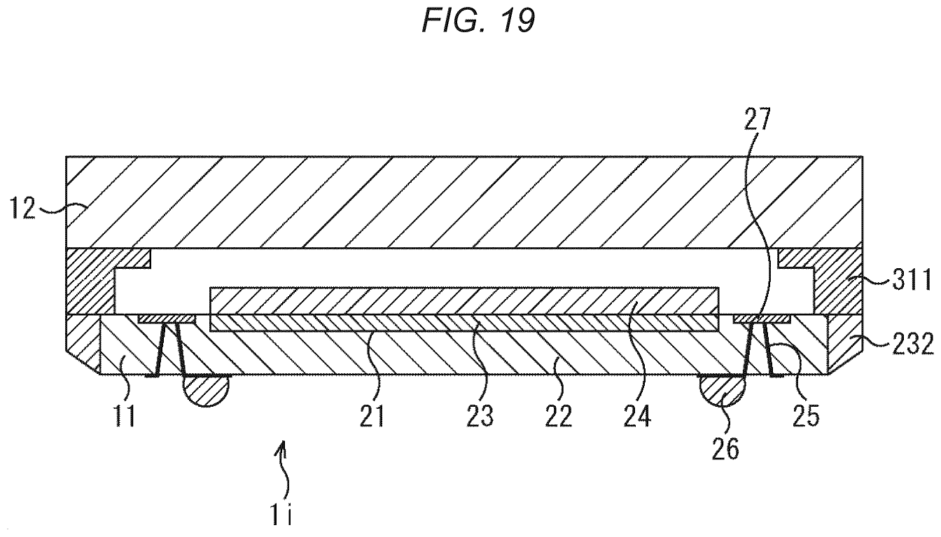

FIG. 19 is a diagram depicting a configuration example of an imaging device 1i according to a ninth embodiment.

The imaging device 1i depicted in FIG. 19 is the same as the imaging device 1g depicted in FIG. 13 except that a bonding resin 311 provided between the imaging element chip 11 and the cover glass 12 has an eaves-like shape.

The bonding resin 311 depicted in FIG. 19 has a hexagonal shape. A side of the bonding resin 311 bonded to the cover glass 12 is formed to be longer than a side bonded to the imaging element chip 11 (bonding resin 232). In a case where the bonding resin 311 is divided into an upper quadrilateral and a lower quadrilateral in the drawing, the upper quadrilateral is bonded to the cover glass 12, and the lower quadrilateral is bonded to the imaging element chip 11 (bonding resin 232). An area of the upper quadrilateral bonded to the cover glass 12 is larger than an area of the lower quadrilateral bonded to the imaging element chip 11 (bonding resin 232). A part of the bonding resin 232 has a recess, and the recess is a portion other than the eaves.

In the imaging device 1i, the bonding resin 311 located adjacent to the cover glass 12 is formed in a shape extending (protruding) toward the cavity relative to the bonding resin 311 located adjacent to the imaging element chip 11. The use of the bonding resin 311 having such an eaves-like shape makes it possible to suppress stray light caused by the ends of the bonding resin 311.

Furthermore, an area where the bonding resin 311 and the cover glass 12 are in contact with each other can be increased, and bonding strength between the bonding resin 311 and the cover glass 12 can be further increased accordingly. An area where the bonding resin 311 and the imaging element chip 11 are in contact with each other can be increased, and bonding strength between the bonding resin 311 and the imaging element chip 11 can also be increased accordingly.

The imaging device 1i may have a configuration where, as with the imaging device 1b (FIG. 8) and the imaging device 1c (FIG. 9), a protective film corresponding to the protective film 101 (111) is formed on the back surface of the imaging element chip 11.

### Configuration of Imaging Device According to Tenth Embodiment

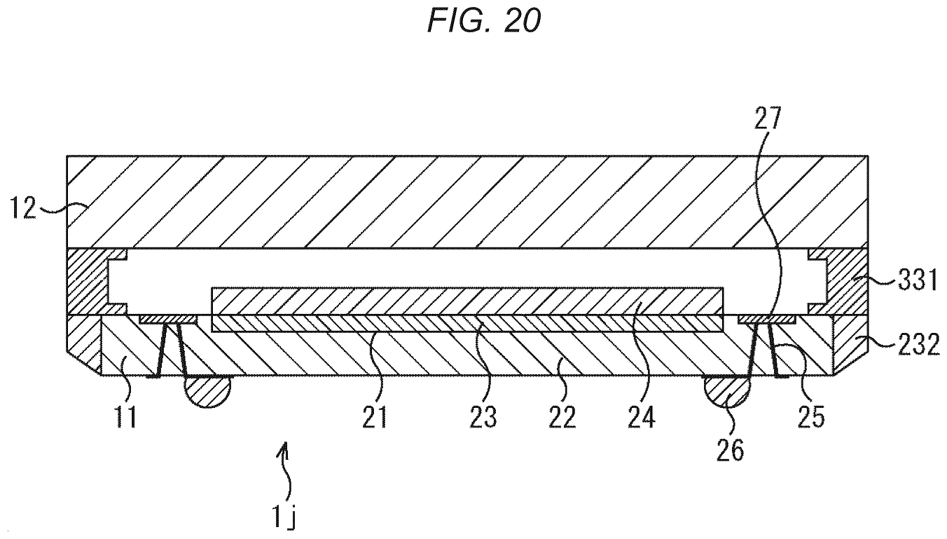

FIG. 20 is a diagram depicting a configuration example of an imaging device 1j according to a tenth embodiment.

The imaging device 1j depicted in FIG. 20 is the same as the imaging device 1i depicted in FIG. 19 except that a bonding resin 331 provided between the imaging element chip 11 and the cover glass 12 is formed with upper and lower portions having an eaves-like shape.

The bonding resin 331 depicted in FIG. 20 has an octagonal shape. A side of the bonding resin 331 bonded to the cover glass 12 and a side bonded to the imaging element chip 11 (bonding resin 232) are formed with about the same length, and a side of the bonding resin 331 adjacent to the cavity has a recessed shape in the middle.

In a case where the bonding resin 331 is divided into an upper quadrilateral, a middle quadrilateral, and a lower quadrilateral in the drawing, the upper quadrilateral is bonded to the cover glass 12, and the lower quadrilateral is bonded to the imaging element chip 11 (bonding resin 232). An area of the upper quadrilateral bonded to the cover glass 12 is about the same as an area of the lower quadrilateral bonded to the imaging element chip 11 (bonding resin 232). In a case of comparing with the middle quadrilateral, the middle quadrilateral is formed with a small area as compared with the area of the upper quadrilateral bonded to the cover glass 12 and the area of the lower quadrilateral bonded to the imaging element chip 11 (bonding resin 232).

In the imaging device 1j, the bonding resin 331 located adjacent to the cover glass 12 is formed in a shape extending (protruding) toward the cavity relative to the middle bonding resin 331. Similarly, in the imaging device 1j, the bonding resin 331 located adjacent to the imaging element chip 11 (bonding resin 232) is formed in a shape extending (protruding) toward the cavity relative to the middle bonding resin 331. Forming the upper and lower portions of the bonding resin 331 in an eaves-like shape makes it possible to suppress stray light caused by the ends of the bonding resin 331.

An area where the bonding resin 331 and the cover glass 12 are in contact with each other can be increased, and bonding strength between the bonding resin 331 and the cover glass 12 can be further increased accordingly. An area where the bonding resin 331 and the imaging element chip 11 are in contact with each other can be increased, and bonding strength between the bonding resin 331 and the imaging element chip 11 can also be increased accordingly.

The imaging device 1j may have a configuration where, as with the imaging device 1b (FIG. 8) and the imaging device 1c (FIG. 9), a protective film corresponding to the protective film 101 (111) is formed on the back surface of the imaging element chip 11.

### Configuration of Imaging Device According to Eleventh Embodiment

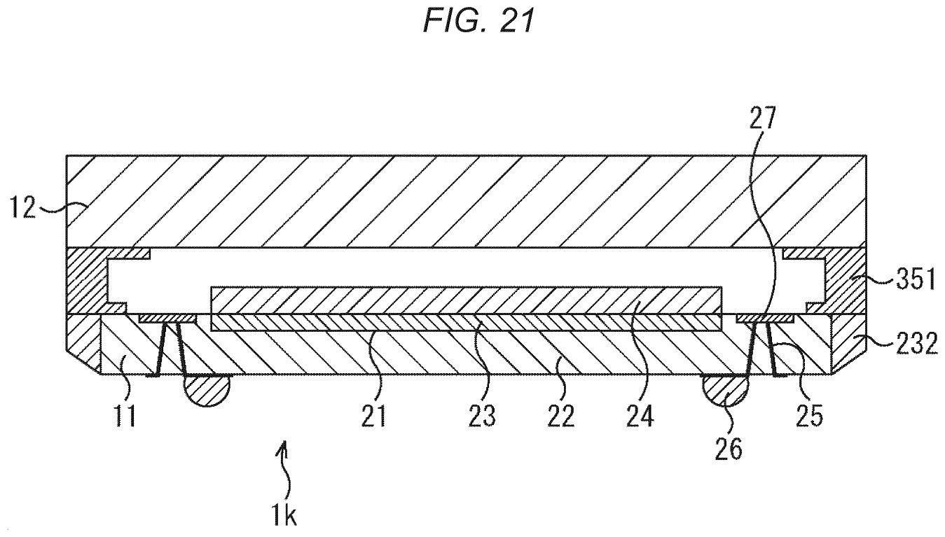

FIG. 21 is a diagram depicting a configuration example of an imaging device 1k according to an eleventh embodiment.

The imaging device 1k depicted in FIG. 21 is the same as the imaging device 1j depicted in FIG. 20 except that a bonding resin 351 provided between the imaging element chip 11 and the cover glass 12 is formed in a shape with the upper eaves (protrusion) and the lower eaves (protrusion) different in length.

A side of the bonding resin 351 bonded to the cover glass 12 depicted in FIG. 21 is formed to be longer than a side of the bonding resin 351 bonded to the imaging element chip 11 (bonding resin 232), and a side of the bonding resin 351 adjacent to the cavity has a recessed shape in the middle. In a case where the bonding resin 351 is divided into an upper quadrilateral, a middle quadrilateral, and a lower quadrilateral in the drawing, the upper quadrilateral is bonded to the cover glass 12, and the lower quadrilateral is bonded to the imaging element chip 11 (bonding resin 232). An area of the upper quadrilateral bonded to the cover glass 12 is larger than an area of the lower quadrilateral bonded to the imaging element chip 11 (bonding resin 232).

In the imaging device 1k, the bonding resin 351 located adjacent to the cover glass 12 is formed in a shape extending (protruding) toward the cavity relative to the middle bonding resin 351. Similarly, in the imaging device 1k, the bonding resin 351 located adjacent to the imaging element chip 11 (bonding resin 232) is formed in a shape extending (protruding) toward the cavity relative to the middle bonding resin 351. Forming the upper and lower portions of the bonding resin 351 in an eaves-like shape makes it possible to suppress stray light caused by the ends of the bonding resin 351.

An area where the bonding resin 351 and the cover glass 12 are in contact with each other can be increased, and bonding strength between the bonding resin 351 and the cover glass 12 can be further increased accordingly. An area where the bonding resin 351 and the imaging element chip 11 are in contact with each other can be increased, and bonding strength between the bonding resin 351 and the imaging element chip 11 can also be increased accordingly.

The imaging device 1k may have a configuration where, as with the imaging device 1b (FIG. 8) and the imaging device 1c (FIG. 9), a protective film corresponding to the protective film 101 (111) is formed on the back surface of the imaging element chip 11.

### Configuration of Imaging Device According to Twelfth Embodiment

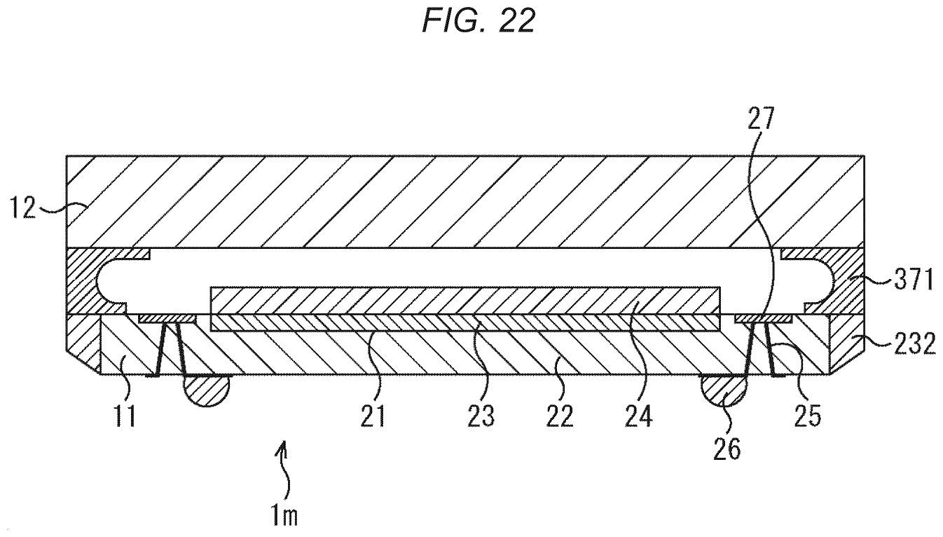

FIG. 22 is a diagram depicting a configuration example of an imaging device 1m according to a twelfth embodiment.

The imaging device 1m depicted in FIG. 22 is the same as the imaging device 1k depicted in FIG. 21 except that a bonding resin 371 provided between the imaging element chip 11 and the cover glass 12 is formed in a semicircular arc shape, in other words, a curved shape.

The bonding resin 371 has an upper eaves (protrusion) and a lower eaves (protrusion) different in length, and a middle portion formed in an arc shape. Forming the upper and lower portions of the bonding resin 371 in an eaves-like shape makes it possible to suppress stray light caused by the ends of the bonding resin 371.

An area where the bonding resin 371 and the cover glass 12 are in contact with each other can be increased, and bonding strength between the bonding resin 371 and the cover glass 12 can be further increased accordingly. An area where the bonding resin 371 and the imaging element chip 11 are in contact with each other can be increased, and bonding strength between the bonding resin 371 and the imaging element chip 11 can also be increased accordingly.

The imaging device 1m may have a configuration where, as with the imaging device 1b (FIG. 8) and the imaging device 1c (FIG. 9), a protective film corresponding to the protective film 101 (111) is formed on the back surface of the imaging element chip 11.

### Configuration of Imaging Device According to Thirteenth Embodiment

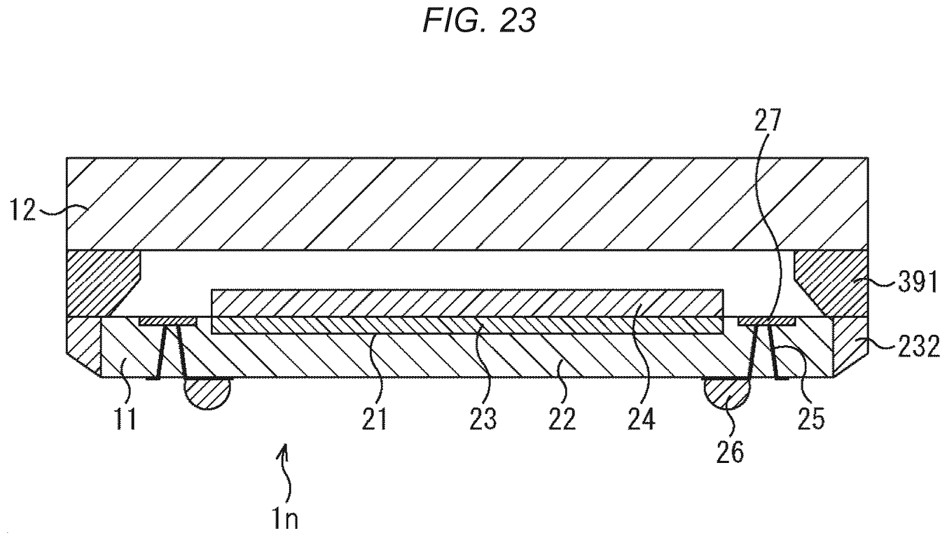

FIG. 23 is a diagram depicting a configuration example of an imaging device 1n according to a thirteenth embodiment.

The imaging device 1n depicted in FIG. 23 is the same as the imaging device 1g depicted in FIG. 13 except that a bonding resin 391 provided between the imaging element chip 11 and the cover glass 12 has a tapered shape.

The bonding resin 391 depicted in FIG. 23 is formed in a pentagonal shape, and has one of the two sides located adjacent to the cavity formed at an angle. In a case where the bonding resin 391 is divided into an upper quadrilateral and a lower pentagon in the drawing, the upper quadrilateral is bonded to the cover glass 12, and the lower pentagon is bonded to the imaging element chip 11 (bonding resin 232). Among the five sides of the lower pentagon, one side located adjacent to the cavity is formed at an angle and in a shape that becomes smaller from the cover glass 12 side (upper quadrilateral side) toward the imaging element chip 11 (bonding resin 232) side. An area of the upper quadrilateral bonded to the cover glass 12 is larger than an area of the lower pentagon bonded to the imaging element chip 11 (bonding resin 232).

It can also be said that the imaging device 1n depicted in FIG. 23 has a structure based on a combination of the imaging device Id having the bonding resin 121 depicted in FIG. 10 formed in a tapered shape and the bonding resin 311 having an eaves-like shape depicted in FIG. 19. The upper quadrilateral bonded to the cover glass 12 is formed in an eaves-like shape, and the lower pentagon bonded to the imaging element chip 11 is formed in a tapered shape. The use of the bonding resin 391 having such an eaves-like shape makes it possible to suppress stray light caused by the ends of the bonding resin 391.

An area where the bonding resin 391 and the cover glass 12 are in contact with each other can be increased, and bonding strength between the bonding resin 391 and the cover glass 12 can be further increased accordingly. An area where the bonding resin 391 and the imaging element chip 11 are in contact with each other can be increased, and bonding strength between the bonding resin 391 and the imaging element chip 11 can also be increased accordingly.

The imaging device 1n may have a configuration where, as with the imaging device 1b (FIG. 8) and the imaging device 1c (FIG. 9), a protective film corresponding to the protective film 101 (111) is formed on the back surface of the imaging element chip 11.

### Configuration of Imaging Device According to Fourteenth Embodiment

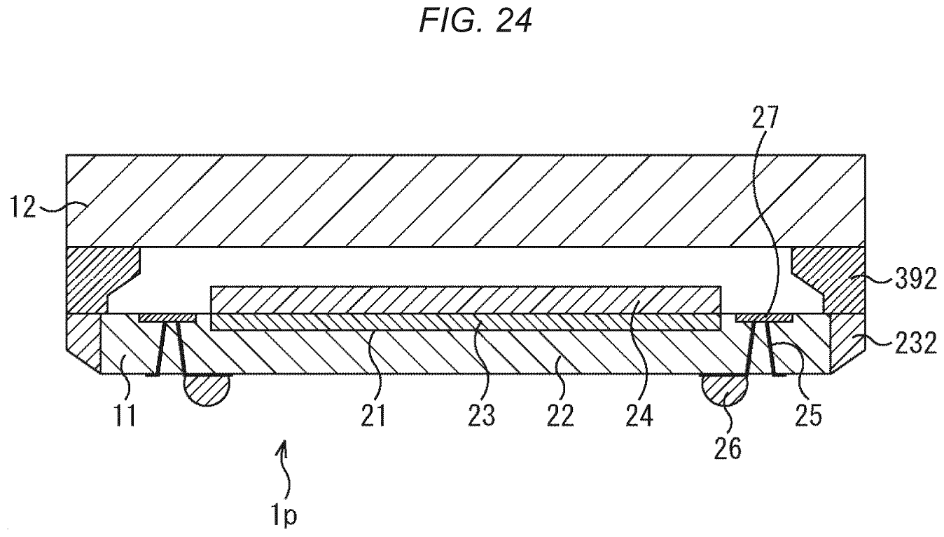

FIG. 24 is a diagram depicting a configuration example of an imaging device 1p according to a fourteenth embodiment.

The imaging device 1p depicted in FIG. 24 is the same as the imaging device 1n depicted in FIG. 23 except that a bonding resin 392 provided between the imaging element chip 11 and the cover glass 12 has a tapered shape as with the bonding resin 391 (FIG. 23), but the tapered shape is positioned in the middle.

The bonding resin 392 is formed in a hexagonal shape, and one of the three sides located adjacent to the cavity is formed at an angle (tapered shape). In a case where the bonding resin 392 is divided into an upper quadrilateral, a middle pentagon, and a lower quadrilateral in the drawing, the upper quadrilateral is bonded to the cover glass 12, and the lower quadrilateral is bonded to the imaging element chip 11 (bonding resin 232). Among the five sides of the middle pentagon, one side located adjacent to the cavity is formed at an angle and in a shape that becomes smaller from the upper quadrilateral side toward the lower quadrilateral side. The use of the bonding resin 392 having such a shape makes it possible to suppress stray light caused by the ends of the bonding resin 392.

An area where the bonding resin 392 and the cover glass 12 are in contact with each other can be increased, and bonding strength between the bonding resin 392 and the cover glass 12 can be further increased accordingly. An area where the bonding resin 392 and the imaging element chip 11 are in contact with each other can be increased, and bonding strength between the bonding resin 392 and the imaging element chip 11 can also be increased accordingly.

The imaging device 1p may have a configuration where, as with the imaging device 1b (FIG. 8) and the imaging device 1c (FIG. 9), a protective film corresponding to the protective film 101 (111) is formed on the back surface of the imaging element chip 11.

### Configuration of Imaging Device According to Fifteenth Embodiment

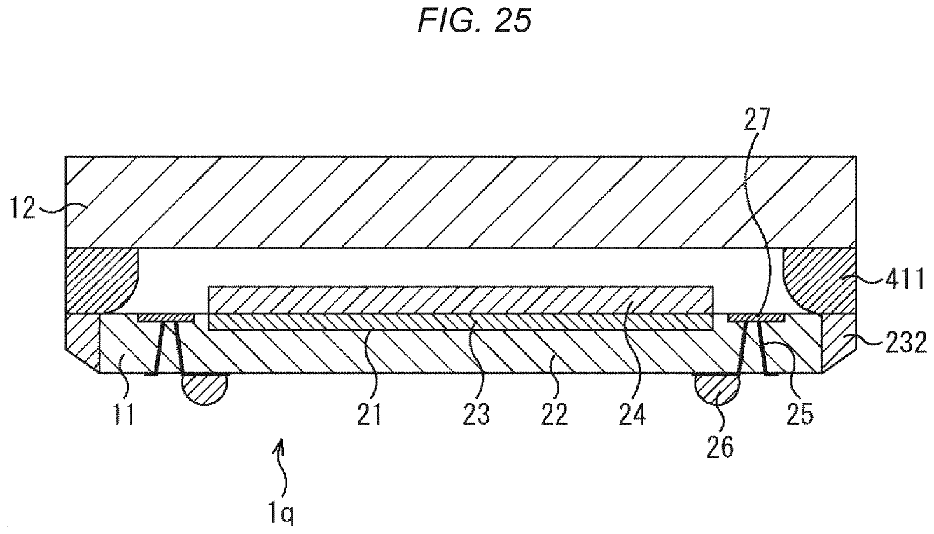

FIG. 25 is a diagram depicting a configuration example of an imaging device 1q according to a fifteenth embodiment.

The imaging device 1q depicted in FIG. 25 is the same as the imaging device 1n depicted in FIG. 23 except that the tapered portion of the bonding resin 391 (FIG. 23) is formed in a curved shape.

In a case where a bonding resin 411 depicted in FIG. 25 is divided into an upper portion and a lower portion in the drawing, the upper portion is quadrilateral, and the lower portion is quadrilateral with one side formed in a curved shape. The upper quadrilateral is bonded to the cover glass 12, and the lower quadrilateral is bonded to the imaging element chip 11 (bonding resin 232). Among the four sides of the lower quadrilateral, one side located adjacent to the cavity is formed in a curved shape, that is, an arc shape in the example depicted in FIG. 25. An area of the upper quadrilateral bonded to the cover glass 12 is larger than an area of the lower quadrilateral bonded to the imaging element chip 11 (bonding resin 232).

Even the use of the bonding resin 411 having such a shape makes it possible to suppress stray light caused by the ends of the bonding resin 411. An area where the bonding resin 411 and the cover glass 12 are in contact with each other can be increased, and bonding strength between the bonding resin 411 and the cover glass 12 can be further increased accordingly. An area where the bonding resin 411 and the imaging element chip 11 are in contact with each other can be increased, and bonding strength between the bonding resin 411 and the imaging element chip 11 can also be increased accordingly.

The imaging device 1n may have a configuration where, as with the imaging device 1b (FIG. 8) and the imaging device 1c (FIG. 9), a protective film corresponding to the protective film 101 (111) is formed on the back surface of the imaging element chip 11.

### Configuration of Imaging Device According to Sixteenth Embodiment

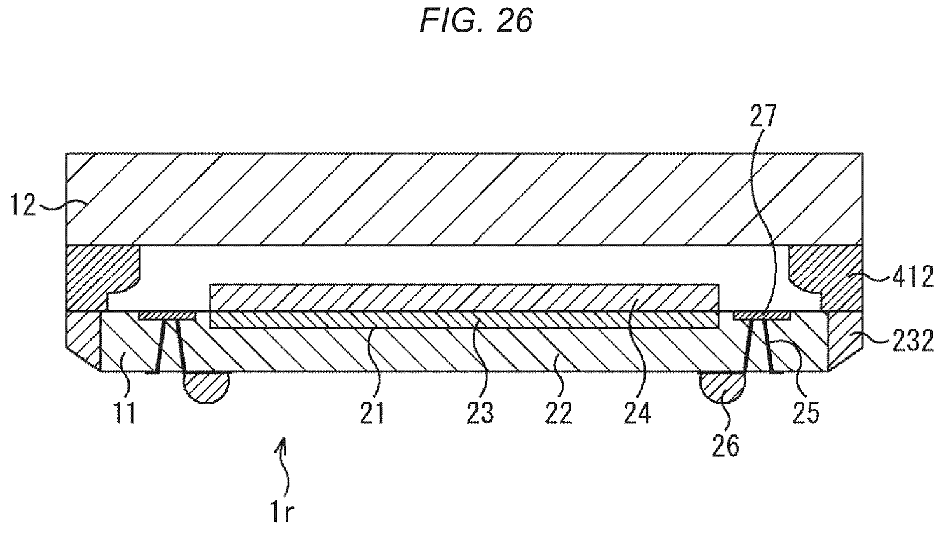

FIG. 26 is a diagram depicting a configuration example of an imaging device 1r according to a sixteenth embodiment.

The imaging device 1r depicted in FIG. 26 is the same as the imaging device 1p depicted in FIG. 24 except that the tapered portion of the bonding resin 391 (FIG. 24) is formed in a curved shape.

In a case where a bonding resin 412 depicted in FIG. 26 is divided into an upper portion, a middle portion, and a lower portion in the drawing, the upper portion is quadrilateral, the middle portion is quadrilateral with one side formed in a curved shape, and the lower portion is quadrilateral. The upper quadrilateral is bonded to the cover glass 12, and the lower quadrilateral is bonded to the imaging element chip 11 (bonding resin 232). Among the four sides of the middle quadrilateral, one side located adjacent to the cavity is formed in a curved shape, that is, an arc shape in the example depicted in FIG. 24. An area of the upper quadrilateral bonded to the cover glass 12 is larger than an area of the lower quadrilateral bonded to the imaging element chip 11 (bonding resin 232).

Even the use of the bonding resin 412 having such a shape makes it possible to suppress stray light caused by the ends of the bonding resin 412. An area where the bonding resin 412 and the cover glass 12 are in contact with each other can be increased, and bonding strength between the bonding resin 412 and the cover glass 12 can be further increased accordingly. An area where the bonding resin 412 and the imaging element chip 11 are in contact with each other can be increased, and bonding strength between the bonding resin 412 and the imaging element chip 11 can also be increased accordingly.

The imaging device 1n may have a configuration where, as with the imaging device 1b (FIG. 8) and the imaging device 1c (FIG. 9), a protective film corresponding to the protective film 101 (111) is formed on the back surface of the imaging element chip 11.

### Configuration of Electronic Apparatus

The imaging device described above can be applied to general electronic apparatuses using a packaged imaging device as an image capturing unit (photoelectric conversion unit), such as an imaging device such as a digital still camera and a video camera, a mobile terminal device having an imaging function such as a mobile phone, and a copying machine using an imaging device as an image reading unit.

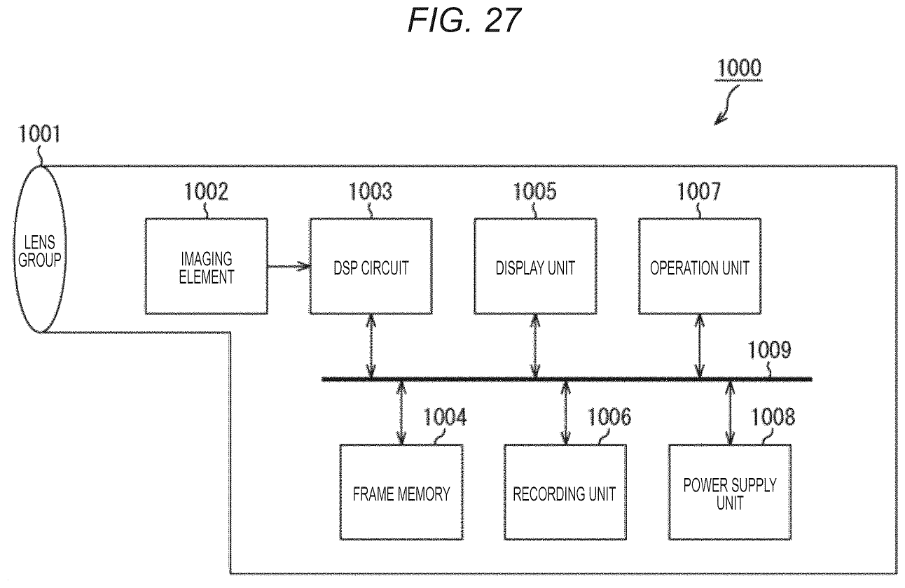

FIG. 27 is a block diagram depicting a configuration example of an electronic apparatus, such as an imaging device, according to the present technology. As depicted in FIG. 27, an imaging device 1000 according to the present technology includes an optical system including a lens group 1001 and the like, an imaging element (imaging device) 1002, a DSP circuit 1003, a frame memory 1004, a display device 1005, a recording device 1006, an operation system 1007, a power supply system 1008, and the like. Then, the DSP circuit 1003, the frame memory 1004, the display device 1005, the recording device 1006, the operation system 1007, and the power supply system 1008 are connected to each other via a bus line 1009.

The lens group 1001 captures incident light (image light) from a subject and forms an image on an imaging surface of the imaging element 1002. The imaging element 1002 converts the amount of the incident light, the image of which is formed on the imaging surface by the lens group 1001, into an electric signal on a pixel-by-pixel basis, and outputs the electric signal as a pixel signal.

The display device 1005 includes a panel display device such as a liquid crystal display device or an organic electro luminescence (EL) display device, and displays a moving image or a still image captured by the imaging element 1002. The recording device 1006 records the moving image or the still image captured by the imaging element 1002 on a recording medium such as a video tape or a digital versatile disk (DVD).

The operation system 1007 issues operation commands for various functions of the imaging device according to an operation performed by a user. The power supply system 1008 appropriately supplies various power serving as operation power for the DSP circuit 1003, the frame memory 1004, the display device 1005, the recording device 1006, and the operation system 1007, to these power supply targets.

The imaging device having the above-described configuration can be used as an imaging device such as a video camera, a digital still camera, and a camera module for a mobile device such as a mobile phone. Then, in the imaging device, the above-described imaging device can be used as the imaging element 1002.

### Application Example to Endoscopic Surgery System

The technology according to an embodiment of the present disclosure (present technology) can be applied to various products. For example, the technology according to an embodiment of the present disclosure may be applied to an endoscopic surgery system.

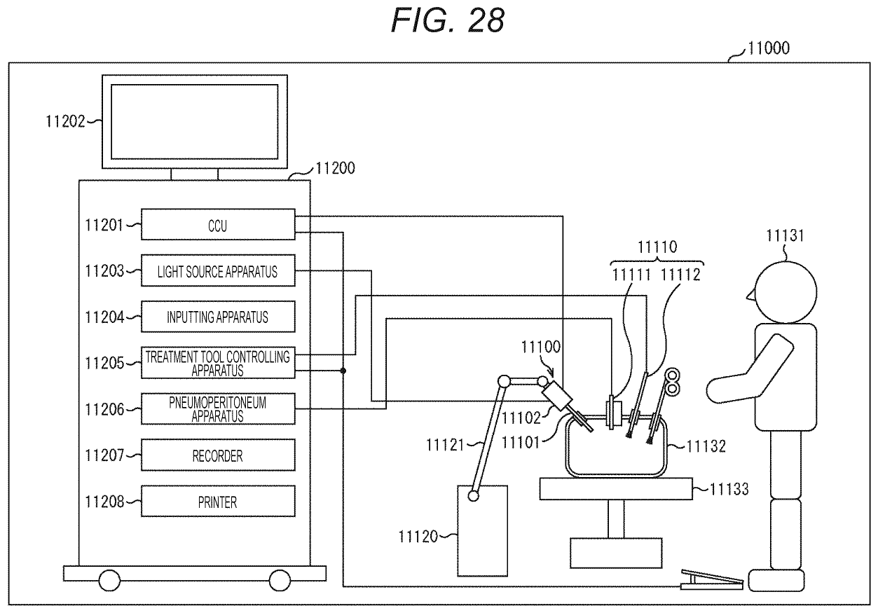

FIG. 28 is a view depicting an example of a schematic configuration of an endoscopic surgery system to which the technology according to an embodiment of the present disclosure (present technology) can be applied.

In FIG. 28, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

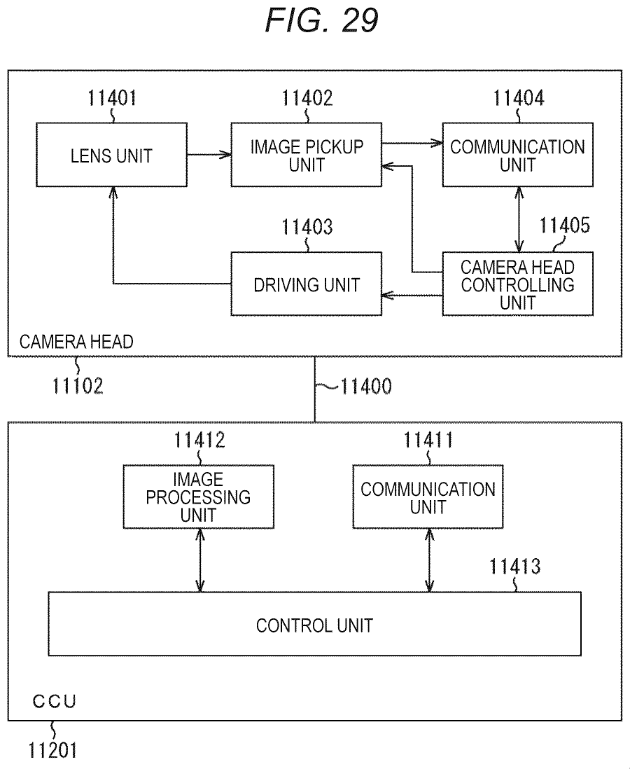

FIG. 29 is a block diagram depicting an example of a functional configuration of the camera head 11102 and the CCU 11201 depicted in FIG. 28.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

In the present specification, the system represents the entire device including a plurality of devices.

Note that the effects described in the present description are merely examples and are not limited, and other effects may be provided.

Note that the embodiments of the present technology are not limited to the above-described embodiments, and various changes can be made without departing from the gist of the present technology.

Note that, the present technology may also have the following configurations.
(1)

An imaging device including:
a chip on which a photoelectric conversion element is formed;
a cover glass;
a first bonding portion that bonds the chip and the cover glass together; and
a second bonding portion bonded to the first bonding portion and the chip, in which
a bonding surface where the first bonding portion and the second bonding portion are bonded is parallel to the cover glass.
(2)

The imaging device according to the above (1), in which
the bonding surface is flush with a front surface of the chip.
(3)

The imaging device according to the above (1) or (2), in which
a width of the bonding between the first bonding portion and the chip is smaller than a width of the bonding between the first bonding portion and the cover glass.
(4)

The imaging device according to any one of the above (1) to (3), in which
the first bonding portion and the second bonding portion include the same material.
(5)

The imaging device according to any one of the above (1) to (3), in which
the first bonding portion includes a colored material, and the second bonding portion includes a material with high adhesiveness.
(6)

The imaging device according to any one of the above (1) to (5), in which
the second bonding portion is formed on a side surface of the chip and a surface of the chip on which an external connection terminal is formed.
(7)

The imaging device according to any one of the above (1) to (6), in which
at least a part of one side of the first bonding portion is formed at an angle between the chip and the cover glass.
(8)

The imaging device according to the above (1), in which
at least a part of one side of the first bonding portion is formed in a curved shape between the chip and the cover glass.
(9)

The imaging device according to the above (1), in which
at least a part of one side of the first bonding portion is formed in a recessed shape.
(10)

The imaging device according to the above (1), in which
the first bonding portion includes a material with high thermal conductivity.
(11)

The imaging device according to the above (1), in which
the first bonding portion includes metal.
(12)

An electronic apparatus including:
an imaging device including
a chip on which a photoelectric conversion element is formed,
a cover glass,
a first bonding portion that bonds the chip and the cover glass together, and
a second bonding portion bonded to the first bonding portion and the chip, in which
a bonding surface where the first bonding portion and the second bonding portion are bonded is parallel to the cover glass; and
a processing unit that processes a signal transmitted from the imaging device.

### REFERENCE SIGNS LIST

1 Imaging device
11 Imaging element chip
12 Cover glass
21 Effective pixel region
22 Silicon substrate
23 Photoelectric conversion element
24 Color filter layer
25 Wiring
26 External connection terminal
27 Surface electrode
31 Bonding resin
32 Bonding resin
33 Interface
34 Bonding resin
61 Semiconductor wafer
62 Protective sheet
71 Glass substrate
72 Protective sheet
73 Non-light transmitting resin
101 Protective film
111 Protective film
112 Bonding resin
121 Bonding resin
131 Bonding resin

What is claimed is:

1. An imaging device, comprising:
a chip on which a photoelectric conversion element is formed;
a cover glass;
a first bonding portion that bonds the chip and the cover glass together; and
a second bonding portion bonded to the first bonding portion and the chip, wherein
a bonding surface where the first bonding portion and the second bonding portion are bonded is parallel to the cover glass.

2. The imaging device according to claim 1, wherein
the bonding surface is flush with a front surface of the chip.

3. The imaging device according to claim 1, wherein
a width of the bonding between the first bonding portion and the chip is smaller than a width of the bonding between the first bonding portion and the cover glass.

4. The imaging device according to claim 1, wherein
the first bonding portion and the second bonding portion include a same material.

5. The imaging device according to claim 1, wherein
the first bonding portion includes a colored material, and the second bonding portion includes a material with high adhesiveness.

6. The imaging device according to claim 1, wherein
the second bonding portion is formed on a side surface of the chip and a surface of the chip on which an external connection terminal is formed.

7. The imaging device according to claim 1, wherein
at least a part of one side of the first bonding portion is formed at an angle between the chip and the cover glass.

8. The imaging device according to claim 1, wherein
at least a part of one side of the first bonding portion is formed in a curved shape between the chip and the cover glass.

9. The imaging device according to claim 1, wherein
at least a part of one side of the first bonding portion is formed in a recessed shape.

10. The imaging device according to claim 1, wherein
the first bonding portion includes a material with high thermal conductivity.

11. The imaging device according to claim 1, wherein
the first bonding portion includes metal.

12. An electronic apparatus, comprising:
an imaging device including
a chip on which a photoelectric conversion element is formed,
a cover glass,
a first bonding portion that bonds the chip and the cover glass together, and
a second bonding portion bonded to the first bonding portion and the chip, wherein
a bonding surface where the first bonding portion and the second bonding portion are bonded is parallel to the cover glass; and
a processing unit that processes a signal transmitted from the imaging device.
